(19) United States
(12) Patent Application Publication
(10) Pub. No.: US 2016/0163369 A1
(43) Pub. Date: Jun. 9, 2016

(54) MAGNETIC MEMORY DEVICE AND METHOD OF FABRICATING THE SAME

(71) Applicants: Kilho LEE, Hwaseong-si (KR); KyungTae NAM, Suwon-si (KR); Sung Chul LEE, Osan-si (KR)

(72) Inventors: Kilho LEE, Hwaseong-si (KR); KyungTae NAM, Suwon-si (KR); Sung Chul LEE, Osan-si (KR)

(21) Appl. No.: 14/957,550

(22) Filed: Dec. 2, 2015

(30) Foreign Application Priority Data
Dec. 9, 2014 (KR) 10-2014-0175814

(51) Int. Cl. G11C 11/16; H01L 43/08; H01L 27/22; H01L 43/02

(52) U.S. Cl. CPC G11C 11/161; H01L 43/02; H01L 43/08; H01L 27/228

(57) ABSTRACT

Provided is a semiconductor device including magnetic tunnel junctions, which are spaced apart from each other on a substrate, and each of which includes a free magnetic pattern, a first pinned magnetic pattern, and a tunnel barrier pattern therebetween. The semiconductor device further includes a separation structure interposed between the magnetic tunnel junctions. The separation structure includes a second pinned magnetic pattern and a first insulating pattern stacked to each other.

### CROSS-REFERENCE TO RELATED APPLICATIONS

This U.S. non-provisional patent application claims priority under 35 U.S.C. §119 to Korean Patent Application No. 10-2014-0175814, filed on Dec. 9, 2014, in the Korean Intellectual Property Office, the entire contents of which are hereby incorporated by reference.

### BACKGROUND

Example embodiments of the inventive concepts relate to a magnetic memory device and a method of fabricating the same, and in particular, to a magnetic memory device, in which a magnetic tunnel junction with a free magnetic layer and a pinned magnetic layer is provided, and a method of fabricating the same.

Due to their small-size, multifunctionality, and/or low-cost characteristics, semiconductor devices are increasingly being used in consumer, commercial and other electronic devices. For example, semiconductor memory devices for storing data are widely used in various electronic devices. Recently, next-generation semiconductor memory devices (e.g., magnetic memory devices) are being developed for high-speed and non-volatile data-storing operations.

The magnetic memory device may include a magnetic tunnel junction MTJ. A magnetic tunnel junction may include two magnetic layers and a tunnel barrier layer interposed therebetween. Resistance of the magnetic tunnel junction may vary depending on magnetization orientations of the magnetic layers. For example, the resistance of the magnetic tunnel junction may be higher when the magnetic layers have anti-parallel magnetization orientations than when they have parallel magnetization orientations. Such a difference in resistance can be used for data storing operations of the magnetic memory device.

### SUMMARY

According to an example embodiment of the inventive concepts, a semiconductor device may include magnetic tunnel junctions provided spaced apart from each other on a substrate, each of the magnetic tunnel junctions including a free magnetic pattern, a first pinned magnetic pattern, and a tunnel barrier pattern therebetween, and a separation structure interposed between the magnetic tunnel junctions. The separation structure may include a second pinned magnetic pattern and a first insulating pattern stacked on the substrate.

In an example embodiment, the second pinned magnetic pattern may have a top surface positioned at a lower level than those of the magnetic tunnel junctions.

In an example embodiment, the second pinned magnetic pattern may have a bottom surface positioned at a higher level those of the magnetic tunnel junctions.

In an example embodiment, the semiconductor device may further include a capping layer provided to cover side surfaces of the magnetic tunnel junctions. The magnetic tunnel junctions and the second pinned magnetic pattern may be spaced apart from each other with the capping layer interposed therebetween.

In an example embodiment, the capping layer may extend to be interposed between the separation structure and the substrate, and the second pinned magnetic pattern may have a bottom surface in direct contact with the capping layer.

In an example embodiment, the separation structure may further include a second insulating pattern, which is vertically spaced apart from the first insulating pattern with the second pinned magnetic pattern interposed therebetween.

In an example embodiment, the semiconductor device may further include bottom electrodes provided below the magnetic tunnel junctions and top electrodes provided on the magnetic tunnel junctions. When viewed in plan view, each of the magnetic tunnel junctions may be overlapped with a corresponding one of the bottom electrodes and a corresponding one of the top electrodes.

In an example embodiment, the second pinned magnetic pattern may be stacked on the first insulating pattern and may have a top surface substantially coplanar with those of the top electrodes.

In an example embodiment, each of the magnetic tunnel junctions may further include a third pinned magnetic pattern, the first and third pinned magnetic patterns may be vertically spaced apart from each other with the free magnetic pattern interposed therebetween.

In an example embodiment, the first and second pinned magnetic patterns may have first and second magnetization directions, respectively, which is parallel, antiparallel, or perpendicular to each other, and each of which is fixed.

In an example embodiment, the second pinned magnetic pattern may include a plurality of patterns, which are provided spaced apart from each other, between the magnetic tunnel junctions. When viewed in plan view, the magnetic tunnel junctions and the patterns of the second pinned magnetic pattern may be alternatingly arranged in a specific direction.

In an example embodiment, when viewed in plan view, the separation structure extends in between the magnetic tunnel junctions to enclose each of the magnetic tunnel junctions.

In an example embodiment, the semiconductor device may further include a cell gate electrode provided on the substrate, a first impurity region and a second impurity region provided in portions of the substrate positioned at both sides of the cell gate electrode, a source line coupled to the first impurity region, and a contact coupled to the second impurity region. The contact may be connected to a corresponding one of the magnetic tunnel junctions.

In an example embodiment, when viewed in plan view, the separation structure may be overlapped with the source line.

According to another example embodiment of the inventive concepts, a semiconductor device may include magnetic tunnel junctions provided spaced apart from each other on a substrate, each of the magnetic tunnel junctions including a free magnetic pattern, a first pinned magnetic pattern, and a tunnel barrier pattern therebetween, and second pinned magnetic patterns spaced apart from each other and interposed between the magnetic tunnel junctions. When viewed in plan view, the magnetic tunnel junctions and the second pinned magnetic patterns may be alternatingly arranged in a specific direction.

In an example embodiment, the magnetic tunnel junctions may be arranged along first and second directions crossing each other to have a two-dimensional arrangement. The second pinned magnetic patterns may be arranged between the magnetic tunnel junctions and in a third direction crossing both of the first and second directions. Here, all of the first, second, and third directions may be parallel to a top surface of the substrate.

In an example embodiment, the semiconductor device may further include a capping layer covering side surfaces of the magnetic tunnel junctions and extending in between the second pinned magnetic patterns and the substrate, and top electrodes provided on the magnetic tunnel junctions. The second pinned magnetic patterns may have bottom surfaces, which are in direct contact with a top surface of the capping layer, and top surfaces, which are substantially coplanar with those of the top electrodes.

A semiconductor device may include magnetic tunnel junctions provided spaced apart from each other on a substrate, each of the magnetic tunnel junctions including a free magnetic pattern, a first pinned magnetic pattern, and a tunnel barrier pattern therebetween; bottom electrodes provided below the magnetic tunnel junctions and overlapped with the magnetic tunnel junctions, respectively, when viewed in plan view; and a second pinned magnetic pattern provided to fill gap regions between the bottom electrodes.

In an example embodiment, the second pinned magnetic pattern may have a top surface coplanar with those of the bottom electrodes. When viewed in plan view, the second pinned magnetic pattern may be provided to enclose the magnetic tunnel junctions.

In an example embodiment, the second pinned magnetic pattern may have side surfaces in direct contact with those of the bottom electrodes.

In an example embodiment, the semiconductor device may further include a capping layer covering side surfaces of the magnetic tunnel junctions and an interlayered insulating layer on the capping layer. When viewed in a vertical section, the capping layer may be interposed between the second pinned magnetic pattern and the interlayered insulating layer.

In an example embodiment, the semiconductor device may further include a cell gate electrode provided on the substrate, a first impurity region and a second impurity region provided in portions of the substrate positioned at both sides of the cell gate electrode, a source line coupled to the first impurity region, and a contact coupled to the second impurity region. The contact may be connected to a corresponding one of the magnetic tunnel junctions. When viewed in plan view, the second pinned magnetic pattern may be overlapped with the source line and is spaced apart from the contact.

### BRIEF DESCRIPTION OF THE DRAWINGS

Example embodiments of the inventive concepts will be more clearly understood from the following brief description taken in conjunction with the accompanying drawings. The accompanying drawings represent non-limiting, example embodiments as described herein.

FIG. 1 is a circuit diagram illustrating a unit memory cell of a magnetic memory device according to example embodiments of the inventive concepts.

FIGS. 2A, 2B, 3A, and 3B are schematic diagrams illustrating magnetic tunnel junctions according to example embodiments of the inventive concepts.

FIG. 4A is a plan view of a magnetic memory device according to example embodiments of the inventive concepts.

FIG. 4B is a sectional view taken along line I-I′ of FIG. 4A.

FIG. 4C is a sectional view taken along line II-II′ of FIG. 4A.

FIGS. 5A through 5G are sectional views illustrating magnetic tunnel junctions according to example embodiments of the inventive concepts.

FIGS. 6A through 8A are sectional views taken along line I-I′ of FIG. 4A to illustrate a method of fabricating a magnetic memory device according to example embodiments of the inventive concepts.

FIGS. 6B through 8B are sectional views taken along line II-II′ of FIG. 4A to illustrate a method of fabricating a magnetic memory device according to example embodiments of the inventive concepts.

FIG. 9 is a sectional view taken along line II-II′ of FIG. 4A to illustrate a magnetic memory device according to other example embodiments of the inventive concepts.

FIG. 10 is a sectional view taken along line II-II′ of FIG. 4A to illustrate a method of fabricating a magnetic memory device according to other example embodiments of the inventive concepts.

FIGS. 11 through 13 are sectional views taken along line II-II′ of FIG. 4A to illustrate a magnetic memory device according to still other example embodiments of the inventive concepts.

FIG. 14A is a plan view of a magnetic memory device according to further example embodiments of the inventive concepts.

FIG. 14B is a sectional view taken along line I-I′ of FIG. 14A.

FIG. 14C is a sectional view taken along line II-II′ of FIG. 14A.

FIG. 15A is a sectional view taken along line I-I′ of FIG. 14A to illustrate a magnetic memory device according to still further example embodiments of the inventive concepts.

FIG. 15B is a sectional view taken along line II-II′ of FIG. 14A to illustrate a magnetic memory device according to still further example embodiments of the inventive concepts.

FIGS. 16A through 18A are sectional views taken along line I-I′ of FIG. 14A to illustrate a method of fabricating a magnetic memory device according to still further example embodiments of the inventive concepts.

FIGS. 16B through 18B are sectional views taken along line II-II′ of FIG. 14A to illustrate a method of fabricating a magnetic memory device according to still further example embodiments of the inventive concepts.

FIGS. 19 and 20 are block diagrams schematically illustrating electronic devices including a magnetic memory device according to example embodiments of the inventive concepts.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments of the inventive concepts will now be described more fully with reference to the accompanying drawings, in which example embodiments are shown. Example embodiments of the inventive concepts may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments of the inventive concepts are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments of the inventive concepts should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

As appreciated by the present inventive entity, devices and methods of forming devices according to various embodiments described herein may be embodied in microelectronic devices such as integrated circuits, wherein a plurality of devices according to various embodiments described herein are integrated in the same microelectronic device. Accordingly, the cross-sectional view(s) illustrated herein may be replicated in two different directions, which need not be orthogonal, in the microelectronic device. Thus, a plan view of the microelectronic device that embodies devices according to various embodiments described herein may include a plurality of the devices in an array and/or in a two-dimensional pattern that is based on the functionality of the microelectronic device.

The devices according to various embodiments described herein may be interspersed among other devices depending on the functionality of the microelectronic device. Moreover, microelectronic devices according to various embodiments described herein may be replicated in a third direction that may be orthogonal to the two different directions, to provide three-dimensional integrated circuits.

Accordingly, the cross-sectional view(s) illustrated herein provide support for a plurality of devices according to various embodiments described herein that extend along two different directions in a plan view and/or in three different directions in a perspective view. For example, when a single active region is illustrated in a cross-sectional view of a device/structure, the device/structure may include a plurality of active regions and transistor structures (or memory cell structures, gate structures, etc., as appropriate to the case) thereon, as would be illustrated by a plan view of the device/structure.

Unless otherwise defined, all terms (including technical and scientific terms) used herein have the same meaning as commonly understood by one of ordinary skill in the art to which example embodiments of the inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

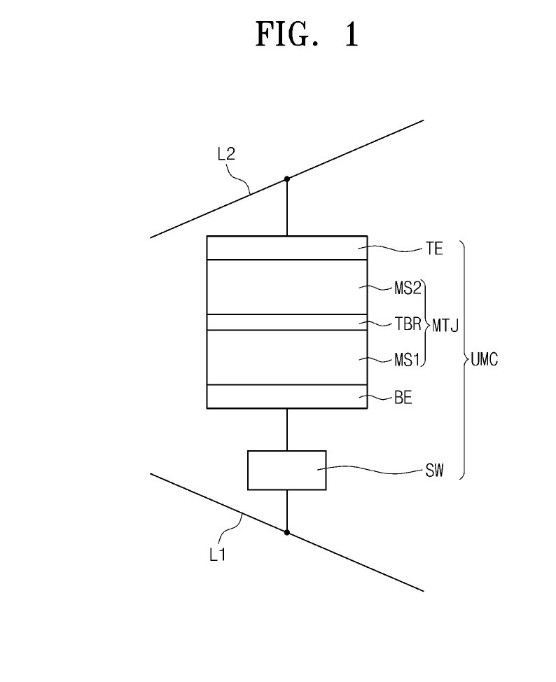

FIG. 1 is a circuit diagram illustrating a unit memory cell of a magnetic memory device according to example embodiments of the inventive concepts.

Referring to FIG. 1, a unit memory cell UMC may be disposed between first and second interconnection lines L1 and L2 crossing each other and may be connected in series to the first and second interconnection lines L1 and L2. The unit memory cell UMC may include a selection device SW and a magnetic tunnel junction MTJ. The selection device SW and the magnetic tunnel junction MTJ may be electrically connected in series to each other. In certain embodiments, one of the first and second interconnection lines L1 and L2 may be used as a word line, and the other may be used as a bit line.

The selection device SW may be configured to selectively control a current flow of an electric current passing through the magnetic tunnel junction MTJ. For example, the selection device SW may be one of a diode, a PNP bipolar transistor, an NPN bipolar transistor, an NMOS field effect transistor (FET), and a PMOS FET. In the case that the selection device SW is a three-terminal switching device, such as bipolar transistors and MOSFETs, an additional interconnection line (not shown) may be connected to the selection device SW.

The magnetic tunnel junction MTJ may include a first magnetic structure MS1, a second magnetic structure MS2, and a tunnel barrier pattern TBR therebetween. Each of the first and second magnetic structures MS1 and MS2 may include at least one magnetic layer made of a magnetic material. In example embodiments, as shown in FIG. 1, the unit memory cell UMC may further include a bottom electrode BE interposed between the first magnetic structure MS1 and the selection device SW and a top electrode TE interposed between the second magnetic structure MS2 and the second interconnection line L2.

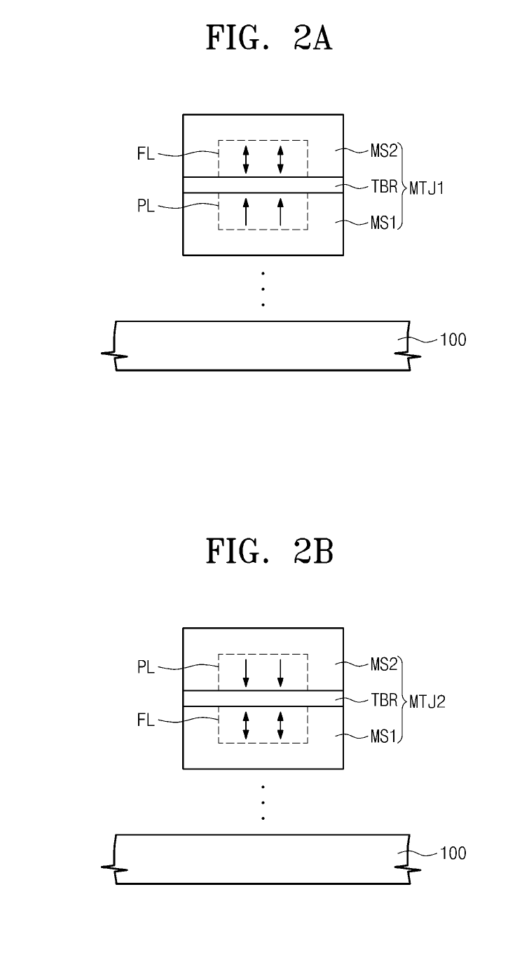

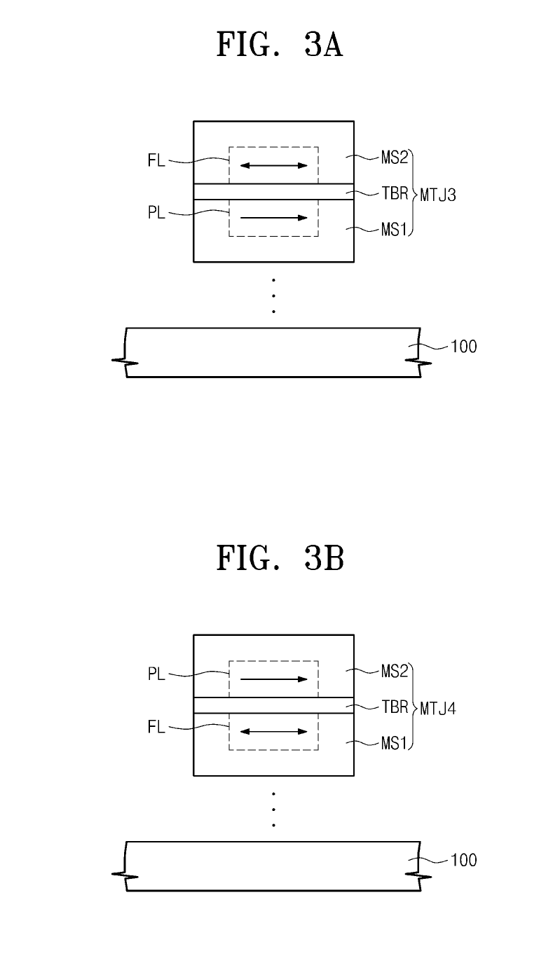

FIGS. 2A, 2B, 3A, and 3B are schematic diagrams illustrating magnetic tunnel junctions according to example embodiments of the inventive concepts.

Referring to FIGS. 2A, 2B, 3A, and 3B, one of the magnetic layers of the first and second magnetic structures MS1 and MS2 may be configured to have a fixed magnetization direction, which is not changed by an external magnetic field generated under usual environments. Hereinafter, for convenience in description, a term ‘pinned magnetic pattern PL’ will be used to represent the magnetic layer having such a fixed magnetization property. The other of the magnetic layers of the first and second magnetic structures MS1 and MS2 may be configured to have a magnetization direction, which can be switched by an external magnetic field applied thereto. Hereinafter, a term ‘free magnetic pattern FL’ will be used to represent the magnetic layer having such a switchable magnetization property. The magnetic tunnel junction MTJ may include at least one free magnetic pattern FL and at least one pinned magnetic pattern PL separated by the tunnel barrier pattern TBR.

Electrical resistance of the magnetic tunnel junction MTJ may be sensitive to a relative orientation of magnetization directions of the free and pinned magnetic patterns FL and PL. For example, the electrical resistance of the magnetic tunnel junction MTJ may be much greater when the relative orientation is antiparallel than when parallel. This means that the electrical resistance of the magnetic tunnel junction MTJ can be controlled by changing the magnetization direction of the free magnetic pattern FL. The magnetic memory devices according to example embodiments of the inventive concept may be realized based on this data-storing mechanism.

As shown in FIGS. 2A, 2B, 3A, and 3B, the first and second magnetic structures MS1 and MS2 of the magnetic tunnel junction MTJ may be sequentially formed on a substrate 100. In this case, based on a relative configuration between the free magnetic pattern FL and the substrate 100 and/or a forming order of and a relative orientation of magnetization between the free and pinned magnetic patterns FL and PL, the magnetic tunnel junction MTJ may be classified into, for example, four types.

As an example, each of the first and second magnetic structures MS1 and MS2 may include at least one magnetic layer, whose magnetization direction is substantially perpendicular to a top surface of the substrate 100. In this case, the magnetic tunnel junction MTJ may be a first type of magnetic tunnel junction MTJ1, in which the pinned and free magnetic patterns PL and FL are provided in the first and second magnetic structures MS1 and MS2, respectively, as shown in FIG. 2A, or a second type of magnetic tunnel junction MTJ2, in which the free and pinned magnetic patterns FL and PL are provided in the first and second magnetic structures MS1 and MS2, respectively, as shown in FIG. 2B.

In addition, each of the first and second magnetic structures MS1 and MS2 may include at least one magnetic layer, whose magnetization direction is substantially parallel to the top surface of the substrate 100. In this case, the magnetic tunnel junction MTJ may be a third type of magnetic tunnel junction MTJ3, in which the pinned and free magnetic patterns PL and FL are provided in the first and second magnetic structures MS1 and MS2, respectively, as shown in FIG. 3A, or a fourth type of magnetic tunnel junction MTJ4, in which the free and pinned magnetic patterns FL and PL are provided in the first and second magnetic structures MS1 and MS2, respectively, as shown in FIG. 3B.

### Magnetic Memory Device

### Example Embodiments

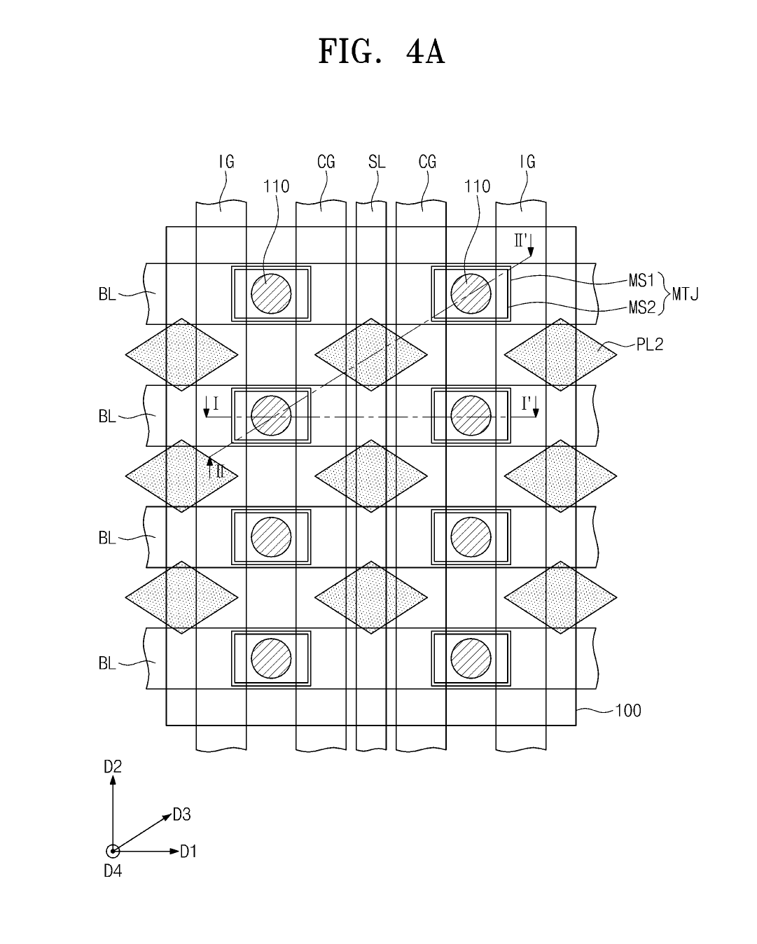

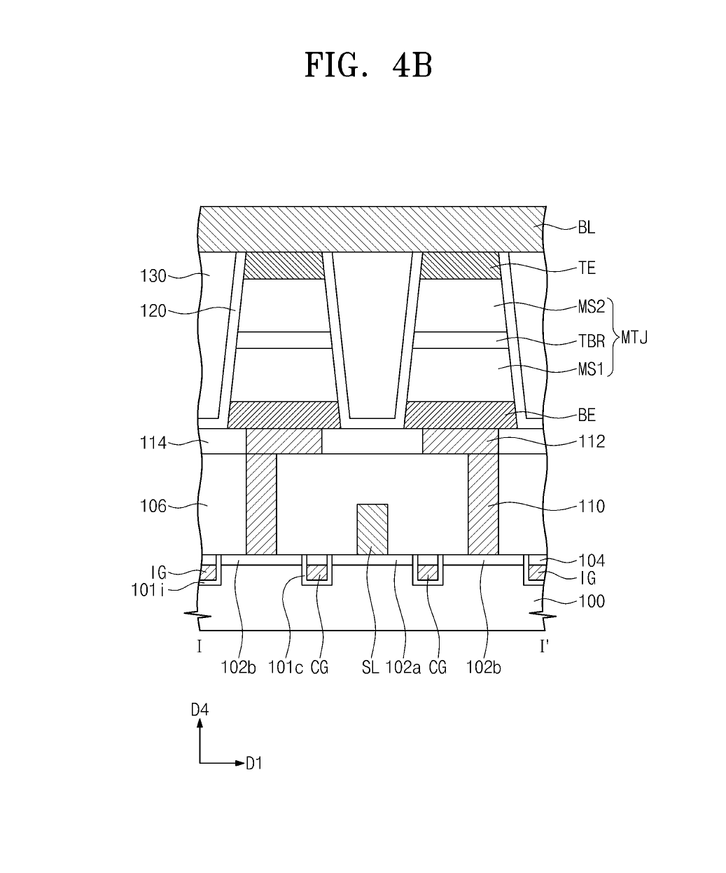

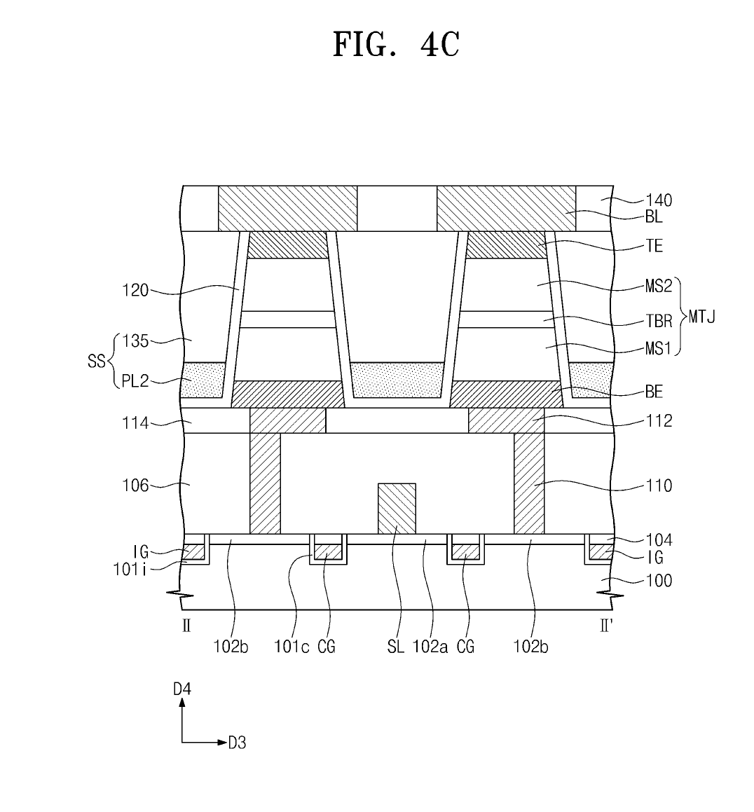

FIG. 4A is a plan view of a magnetic memory device according to example embodiments of the inventive concepts. FIG. 4B is a sectional view taken along line I-I′ of FIG. 4A, and FIG. 4C is a sectional view taken along line II-II′ of FIG. 4A.

Referring to FIGS. 4A through 4C, selection devices may be provided on a substrate 100. The selection devices may be transistors. The transistors may include cell gate electrodes CG provided on the substrate 100. The cell gate electrodes CG may be spaced apart from each other in a first direction D1 and may extend in a second direction D2 crossing the first direction D1. Cell gate dielectric layers 101c may be respectively disposed between the cell gate electrodes CG and the substrate 100. The transistors including the cell gate electrodes CG may include recessed channel regions.

Isolation gate electrodes IG may be disposed spaced apart from each other with a pair of cell gate electrodes CG interposed therebetween. The isolation gate electrodes IG may be spaced apart from each other in the first direction D1 and may extend in the second direction D2. Isolation gate dielectric layers 101i may be respectively disposed between the isolation gate electrodes IG and the substrate 100.

Gate hard mask patterns 104 may be disposed on the cell and isolation gate electrodes CG and IG, respectively. Each of the gate hard mask patterns 104 may have a top surface substantially coplanar with that of the substrate 100.

When the semiconductor memory device is operated, an isolation voltage may be applied to at least one of the isolation gate electrodes IG. This makes it possible to prevent an unintended channel region from being formed below the isolation gate electrodes IG. In other words, the isolation voltage may allow an isolation channel region positioned below each of the isolation gate electrodes IG to be in a turn-off state, and thus, an active region may be defined between the isolation gate electrodes IG.

The cell gate electrodes CG may include at least one of, for example, doped semiconductor materials (e.g., doped silicon), metals (e.g., tungsten, aluminum, titanium, and/or tantalum), conductive metal nitrides (e.g., titanium nitride, tantalum nitride, and/or tungsten nitride), or metal-semiconductor compounds (e.g., metal silicide). The isolation gate electrodes IG may include the same material as the cell gate electrodes CG. The cell gate dielectric layers 101c and the isolation gate dielectric layers 101i may include, for example, at least one of oxide (e.g., silicon oxide), nitride (e.g., silicon nitride), oxynitride (e.g., silicon oxynitride), and/or a high-k dielectric (e.g., insulating metal oxides such as hafnium oxide or aluminum oxide). The gate hard mask patterns 104 may include at least one of oxide (e.g., silicon oxide), nitride (e.g., silicon nitride), or oxynitride (e.g., silicon oxynitride).

First and second impurity regions 102a and 102b may be provided at both sides of each of the cell gate electrodes CG. The first and second impurity regions 102a and 102b may serve as source and drain regions of each of the transistors. The pair of cell gate electrodes CG may share the first impurity region 102a provided between the pair of cell gate electrodes CG. The first and second impurity regions 102a and 102b may be doped to have a different conductivity type from that of the substrate 100.

A source line SL may be provided on the substrate 100 between each pair of cell gate electrodes CG. The source line SL may be electrically coupled to the first impurity region 102a. A pair of selection devices disposed adjacent to each other may share one of the source lines SL interposed therebetween. The source line SL may include at least one of, for example, doped semiconductor materials (e.g., doped silicon), metals (e.g., tungsten, aluminum, titanium, and/or tantalum), conductive metal nitrides (e.g., titanium nitride, tantalum nitride, and/or tungsten nitride), or metal-semiconductor compounds (e.g., metal silicide).

A first interlayered insulating layer 106 may be provided on the substrate 100 to cover the cell and isolation gate electrodes CG and IG and the source line SL. The first interlayered insulating layer 106 may be formed of or include, for example, a silicon oxide layer. Contacts 110 may be provided through the first interlayered insulating layer 106 and may be coupled to the second impurity regions 102b, respectively. In other words, the first impurity region 102a may be coupled to the source line SL, and the second impurity regions 102b may be coupled to the contacts 110. Each of the contacts 110 may have a top surface substantially coplanar with that of the first interlayered insulating layer 106. The contacts 110 may include at least one of metals, conductive metal nitrides, or doped semiconductor materials.

A buried insulating layer 114 may be provided on the first interlayered insulating layer 106. The buried insulating layer 114 may be formed of or include, for example, silicon nitride. Conductive pads 112 may be provided through the buried insulating layer 114 and may be connected to the contacts 110, respectively. Each of the conductive pads 112 may have a top surface substantially coplanar with that of the buried insulating layer 114. The conductive pads 112 may include at least one of metals, conductive metal nitrides, or doped semiconductor materials. The contacts 110 and the conductive pads 112 may be used to connect the second impurity regions 102b to a magnetic tunnel junction, which will be formed in a subsequent process.

Bottom electrodes BE may be provided on the buried insulating layer 114 and may be coupled to the conductive pads 112, respectively. Magnetic tunnel junctions MTJ may be disposed on and connected to the bottom electrodes BE, respectively. Top electrodes TE may be provided on and coupled to the magnetic tunnel junctions MTJ, respectively. The bottom electrodes BE and the top electrodes TE may include at least one of metals, conductive metal nitrides, or doped semiconductor materials.

The magnetic tunnel junctions MTJ may be electrically connected to the second impurity regions 102b through the bottom electrodes BE, the conductive pads 112, and the contacts 110. As shown in FIG. 4A, the magnetic tunnel junctions MTJ may be arranged spaced apart from each other in the first direction D1 and the second direction D2, when viewed in plan view.

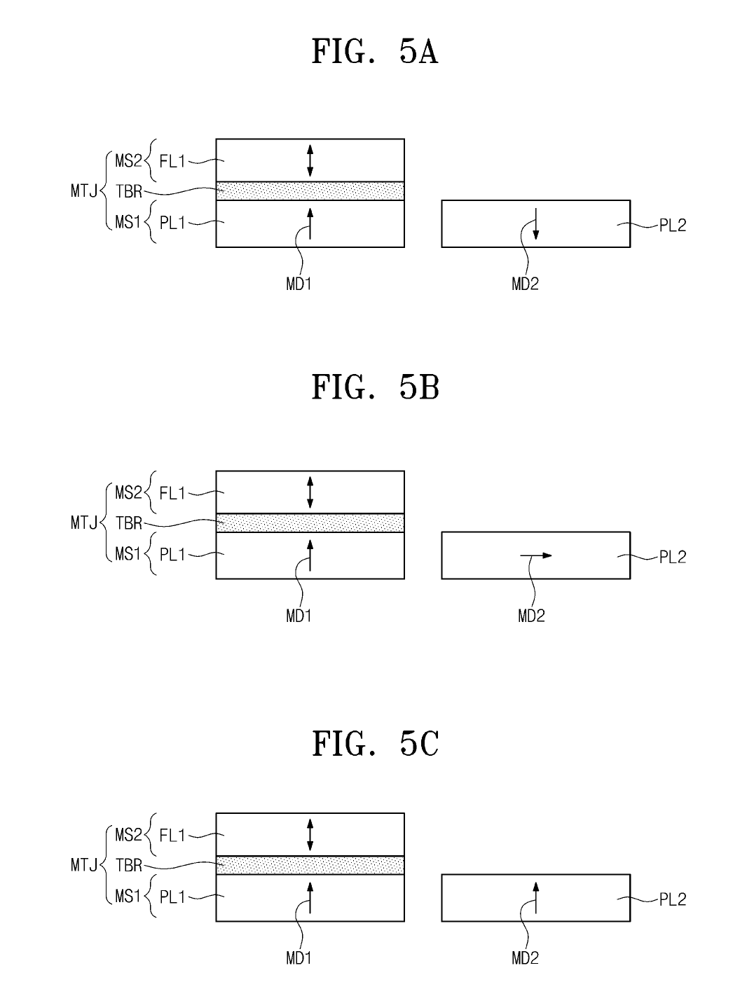

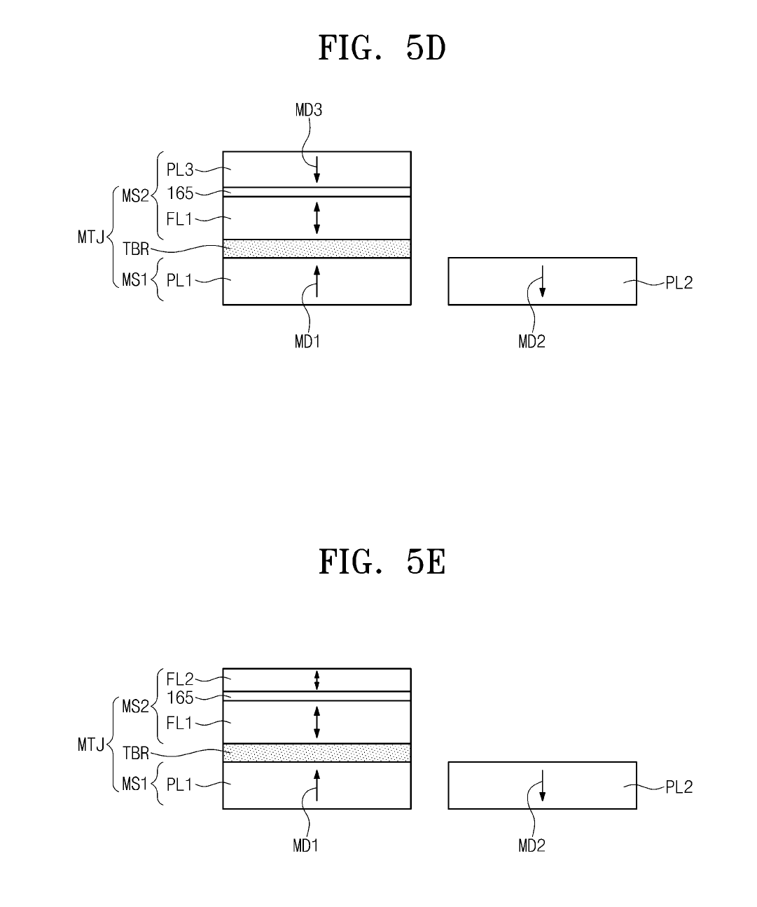

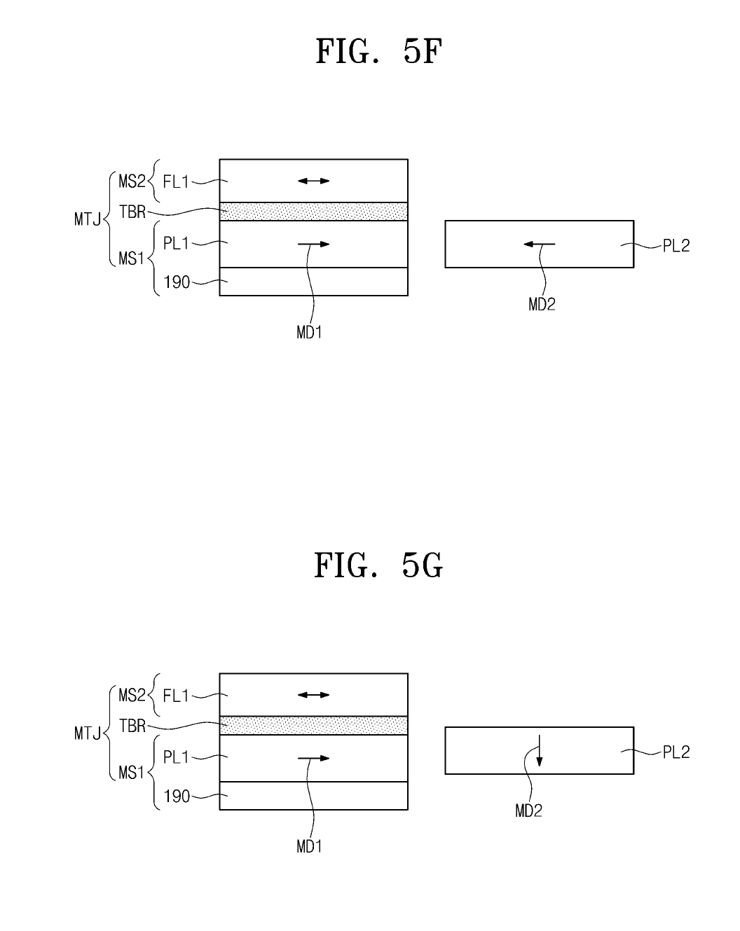

The magnetic tunnel junctions MTJ may include first magnetic structures MS1, which are respectively coupled to the bottom electrodes BE and second magnetic structures MS2, which are respectively coupled to the top electrodes TE. In example embodiments, the first magnetic structures MS1 may include first pinned magnetic patterns PL1, and the second magnetic structures MS2 may include first free magnetic patterns FL1, as will be described in more detail with reference to FIG. 5A. When viewed in plan view, the first magnetic structures MS1 may be overlapped with the second magnetic structures MS2, respectively.

The magnetic tunnel junctions MTJ may further include a tunnel bather patterns TBR disposed between the first magnetic structures MS1 and the second magnetic structures MS2. The magnetic tunnel junctions MTJ will be described in more detail with reference to FIG. 5A.

A capping layer 120 may be provided to cover the side surfaces of the magnetic tunnel junctions MTJ. The capping layer 120 may be extended from the sidewalls of the magnetic tunnel junctions MTJ to cover sidewalls of the top electrodes TE, sidewalls of the bottom electrodes BE, and a top surface of the buried insulating layer 114. The capping layer 120 may have a top surface substantially coplanar with those of the top electrodes TE. The capping layer 120 may include at least one of tantalum oxide, magnesium oxide, titanium oxide, zirconium oxide, hafnium oxide, or zinc oxide.

Separation structures SS may be interposed between the magnetic tunnel junctions MTJ. Each of the separation structures SS may include a second pinned magnetic pattern PL2 and a first insulating pattern 135, which are sequentially stacked on the capping layer 120. The first insulating patterns 135 may be formed of or include, for example, a silicon oxide layer. The separation structures SS may be spaced apart from the magnetic tunnel junctions MTJ with the capping layer 120 interposed therebetween. The separation structures SS may have top surfaces coplanar with those of the top electrodes TE.

As shown in FIG. 4C, the second pinned magnetic patterns PL2 may be provided below the first insulating patterns 135. The second pinned magnetic patterns PL2 may have bottom surfaces in direct contact with the capping layer 120. In other words, the capping layer 120 may be interposed between the second pinned magnetic patterns PL2 and the buried insulating layer 114. The top surfaces of the second pinned magnetic patterns PL2 may be positioned at a lower level than those of the magnetic tunnel junctions MTJ. The second pinned magnetic patterns PL2 will be described in more detail with reference to FIG. 5A.

As shown in FIG. 4A, when viewed in plan view the separation structures SS (i.e., the second pinned magnetic patterns PL2) may be arranged two-dimensionally (i.e., spaced apart from each other in the first and second directions D1 and D2). In addition, the magnetic tunnel junctions MTJ and the second pinned magnetic patterns PL2 may be alternatingly arranged in a third direction D3. The third direction D3 may be a direction crossing both of the first and second directions D1 and D2 and being parallel to the top surface of the substrate 100. The second pinned magnetic patterns PL2 may constitute a plurality of columns, which are parallel to the second direction D2 and are spaced apart from each other in the first direction D1. At least one of the columns of the second pinned magnetic patterns PL2 may be overlapped with the source line SL, when viewed in a plan view. The columns of the second pinned magnetic patterns PL2 and the columns of the magnetic tunnel junctions MTJ may be alternatingly disposed in the first direction D1.

A second interlayered insulating layer 130 may be formed on the buried insulating layer 114 to fill gap regions between or around the lower and top electrodes BE and TE, the magnetic tunnel junctions MTJ, the capping layer 120, and the separation structures SS. As shown in FIG. 4B, the capping layer 120 may be interposed between the second interlayered insulating layer 130 and the magnetic tunnel junctions MTJ. The second interlayered insulating layer 130 may have a top surface, which is substantially coplanar with those of the top electrodes TE and the separation structures SS. The second interlayered insulating layer 130 may be formed of or include, for example, a silicon oxide layer.

In example embodiments, the first insulating patterns 135, which are provided to define the second pinned magnetic patterns PL2, may be continuously connected to the second interlayered insulating layer 130, and in this case, the first insulating patterns 135 and second interlayered insulating layer 130 may constitute a single body.

A third interlayered insulating layer 140 and bit lines BL may be provided on the second interlayered insulating layer 130 and the separation structures SS. The bit lines BL may be provided in the third interlayered insulating layer 140. The bit lines BL may be spaced apart from each other in the second direction D2 and may extend parallel to the first direction D1. Each of the bit lines BL may be coupled to a plurality of top electrodes TE arranged parallel to the first direction D1. The bit lines BL may be formed of or include, for example, at least one of metals or conductive metal nitrides.

FIG. 5A is a sectional view illustrating a magnetic tunnel junction according to example embodiments of the inventive concepts.

Referring to FIG. 5A, the magnetic tunnel junction MTJ may include a first magnetic structure MS1, a second magnetic structure MS2, and a tunnel barrier TBR interposed therebetween. One of the first and second magnetic structures MS1 and MS2 may have a fixed magnetization direction and serve as a fixed layer, and the other may have a magnetization direction, which can be switched to be parallel or antiparallel to that of the fixed layer, and serve as a free layer. For the sake of simplicity, the description that follows will refer to an example of the present embodiment in which the first and second magnetic structures MS1 and MS2 are used as the fixed and free layers, respectively, but in other embodiments, the first and second magnetic structures MS1 and MS2 may be used as the free and fixed layers, respectively.

For example, the first magnetic structure MS1 may include the first pinned magnetic pattern PL1. In other words, the first pinned magnetic pattern PL1 may be provided between the bottom electrode BE (e.g., of FIG. 4B) and the tunnel barrier pattern TBR. The first pinned magnetic pattern PL1 may include a perpendicular magnetic material. As an example, the first pinned magnetic pattern PL1 may include at least one of; a) CoFeTb, in which the relative content of Tb is 10% or more; b) CoFeGd, in which the relative content of Gd is 10% or more; c) CoFeDy; d) FePt with the L10 structure; e) FePd with the L10 structure; f) CoPd with the L10 structure; g) CoPt with the L10 structure; h) CoPt with the hexagonal close packing (HCP) structure; and/or i) alloys containing at least one of materials presented in items of a) to h). As another example, the first pinned magnetic pattern PL1 may include a multi-layered structure including alternatingly-stacked magnetic and non-magnetic layers. The multi-layered structure including the alternatingly-stacked magnetic and non-magnetic layers may include at least one of, for example, (Co/Pt)n, (CoFe/Pt)n, (CoFe/Pd)n, (CoP)n, (Co/Ni)n, (CoNi/Pt)n, (CoCr/Pt)n, and/or (CoCr/Pd)n, where the subscript n denotes the stacking number.

The second magnetic structure MS2 may include the first free magnetic pattern FL1 provided on the tunnel barrier pattern TBR. For example, the first free magnetic pattern FL1 may be provided between the tunnel barrier pattern TBR and the top electrode TE (e.g., of FIG. 4B). The first free magnetic pattern FL1 may include two layers, one of which includes an antiferromagnetic material, and the other of which includes a ferromagnetic material. The layer including the antiferromagnetic material may include at least one of PtMn, IrMn, MnO, MnS, MnTe, MnF₂, FeCl₂, FeO, CoCl₂, CoO, NiCl₂, NiO, or Cr. In certain embodiments, the layer including the antiferromagnetic material may include at least one of precious metals. The precious metals may include ruthenium (Ru), rhodium (Rh), palladium (Pd), osmium (Os), iridium (Ir), platinum (Pt), gold (Au), or silver (Ag). The layer including the ferromagnetic material may include at least one of CoFeB, Fe, Co, Ni, Gd, Dy, CoFe, NiFe, MnAs, MnBi, MnSb, CrO₂, MnOFe₂O₃, FeOFe₂O₃, NiOFe₂O₃, CuOFe₂O₃, MgOFe₂O₃, EuO, or Y₃Fe₅O₁₂.

The second pinned magnetic pattern PL2 may be provided adjacent to the magnetic tunnel junction MTJ. The magnetic tunnel junction MTJ and the second pinned magnetic pattern PL2 may be disposed to have substantially the same disposition and arrangement as that described with reference to FIGS. 4A through 4C. The second pinned magnetic pattern PL2 may include a perpendicular magnetic material (for example, at least one of the above materials enumerated for the first pinned magnetic pattern PL1).

The first and second pinned magnetic patterns PL1 and PL2 may have a magnetization direction substantially perpendicular to the top surface of the substrate 100. Similarly, a magnetization direction of the first free magnetic pattern FL1 may be substantially perpendicular to the top surface of the substrate 100.

In some aspect of the inventive concept, the first pinned magnetic pattern PL1 may be configured to have an easy axis that is substantially perpendicular to the top surface of the substrate 100. The first pinned magnetic pattern PL1 may have a first magnetization direction MD1 that is fixed. The second pinned magnetic pattern PL2 may also be configured to have an easy axis that is substantially perpendicular to the top surface of the substrate 100. The second pinned magnetic pattern PL2 may have a second magnetization direction MD2 that is fixed. The first and second magnetization directions MD1 and MD2 may not be the same. For example, the second magnetization direction MD2 may be antiparallel to the first magnetization direction MD1. In this case, magnetic fields generated from the first and second pinned magnetic patterns PL1 and PL2 may be cancelled to each other and a net or resultant magnetic field from the first and second pinned magnetic patterns PL1 and PL2 may have a lowered magnitude. This makes it possible to reduce influence of the first and second pinned magnetic patterns PL1 and PL2 on a magnetization property of the first free magnetic pattern FL1.

The first free magnetic pattern FL1 may have a magnetization direction which is parallel or antiparallel to the first magnetization direction MD1, and the switching of the magnetization direction of the first free magnetic pattern FL1 may be achieved through a programming operation. For example, the switching of the magnetization direction of the first free magnetic pattern FL1 may be controlled by a spin torque transfer (STT) programming operation. In other words, the magnetization direction of the first free magnetic pattern FL1 may be switched using electrons constituting a program current, based on a spin torque transfer phenomenon.

In example embodiments, the second pinned magnetic pattern PL2 may be provided between the magnetic tunnel junctions MTJ. For example, the second pinned magnetic pattern PL2 may be provided at a position horizontally spaced apart from the first pinned magnetic pattern PL1 and the first free magnetic pattern FL1, independent of the magnetic tunnel junction MTJ, and thus, it is possible to reduce a total thickness of the magnetic tunnel junction MTJ. Further, this makes it possible to easily perform a patterning process for forming the magnetic tunnel junction MTJ. In addition, once the magnetization direction of the first free magnetic pattern FL1 is switched, the switched magnetization direction of the first free magnetic pattern FL1 may be constrained (e.g., to be parallel to the second magnetization direction MD2) by the second pinned magnetic pattern PL2, and this makes it possible to improve stability of the magnetic tunnel junction MTJ.

FIGS. 5B through 5F are sectional views illustrating magnetic tunnel junctions according to other example embodiments of the inventive concept. In the following description of FIGS. 5B through 5F, an element previously described with reference to FIG. 5A may be identified by a similar or identical reference number without repeating an overlapping description thereof, for the sake of brevity.

Referring to FIG. 5B, the second pinned magnetic pattern PL2 may have a second magnetization direction MD2 that is fixed. The second magnetization direction MD2 may be perpendicular to a first magnetization direction MD1 of the first pinned magnetic pattern PL1. In the present embodiment, the second pinned magnetic pattern PL2 may be configured in such a way that a switching property in magnetization direction of the first free magnetic pattern FL1 is influenced by the second magnetization direction MD2. For example, the second pinned magnetic pattern PL2 may be configured in such a way that the magnetization direction of the first free magnetic pattern FL1 can be more easily switched to be antiparallel to the first magnetization direction MD1. In this case, the magnetic tunnel junction MTJ can have a lowered operation current and a higher operation speed.

Referring to FIG. 5C, the second pinned magnetic pattern PL2 may have a second magnetization direction MD2 that is fixed. The second magnetization direction MD2 may be parallel to a first magnetization direction MD1 of the first pinned magnetic pattern PL1.

Referring to FIG. 5D, the second magnetic structure MS2 may include a first free magnetic pattern FL1, a non-magnetic metal pattern 165, and a third pinned magnetic pattern PL3, which are sequentially stacked on the tunnel barrier pattern TBR. The third pinned magnetic pattern PL3 may be spaced apart from the first free magnetic pattern FL1 with the non-magnetic metal pattern 165 interposed therebetween. The third pinned magnetic pattern PL3 may include a perpendicular magnetic material (for example, at least one of the above materials enumerated for the first pinned magnetic pattern PL1 in FIG. 5A). The third pinned magnetic pattern PL3 may include a third magnetization direction MD3 that is fixed. The third magnetization direction MD3 may be parallel to a second magnetization direction MD2 of the second pinned magnetic pattern PL2.

The non-magnetic metal pattern 165 may include a non-magnetic metal material. For example, the non-magnetic metal material may be one of Hf, Zr, Ti, Ta, and any alloy thereof. The non-magnetic metal pattern 165 may be configured to allow the third pinned magnetic pattern PL3 to be magnetically coupled with the first free magnetic pattern FL1. However, in other example embodiments, the non-magnetic metal pattern 165 may be omitted.

Referring to FIG. 5E, the second magnetic structure MS2 may include the first free magnetic pattern FL1, the non-magnetic metal pattern 165, and a second free magnetic pattern FL2, which sequentially stacked on the tunnel barrier pattern TBR. The second free magnetic pattern FL2 may be spaced apart from the first free magnetic pattern FL1 with the non-magnetic metal pattern 165 interposed therebetween.

The non-magnetic metal pattern 165 may include a non-magnetic metal material. Due to the presence of the non-magnetic metal pattern 165, the second free magnetic pattern FL2 may be magnetically coupled with the first free magnetic pattern FL1 in such a way that the second free magnetic pattern FL2 has a magnetization direction parallel to that of the first free magnetic pattern FL1.

The second free magnetic pattern FL2 may include a perpendicular magnetic material (for example, at least one of the above materials enumerated for the first free magnetic pattern FL1 in FIG. 5A).

Referring to FIG. 5F, the first magnetic structure MS1 may include a pinning pattern 190 and the first pinned magnetic pattern PL1, which are sequentially stacked on the substrate. For example, the pinning pattern 190 may be disposed between the bottom electrode BE (e.g., of FIG. 4B) and the first pinned magnetic pattern PL1. In the present embodiment, the first magnetic structure MS1 may be configured to include a pinned magnetic pattern PL constituting a third type of magnetic tunnel junction MTJ3 shown in FIG. 3A. For example, the first pinned magnetic pattern PL1 may have a first magnetization direction MD1 that is fixed and is substantially parallel to the top surface of the substrate 100. The first magnetization direction MD1 of the first pinned magnetic pattern PL1 may be fixed by the pinning pattern 190.

The pinning pattern 190 may include an antiferromagnetic material. For example, the pinning pattern 190 may include at least one of platinum manganese (PtMn), iridium manganese (IrMn), manganese oxide (MnO), manganese sulfide (MnS), manganese tellurium (MnTe), or manganese fluoride (MnF).

The first pinned magnetic pattern PL1 may include a ferromagnetic material. For example, the first pinned magnetic pattern PL1 may include at least one cobalt-iron-boron (CoFeB), cobalt-iron (CoFe), nickel-iron (NiFe), cobalt-iron-platinum (CoFePt), cobalt-iron-palladium (CoFePd), cobalt-iron-chromium (CoFeCr), cobalt-iron-terbium (CoFeTb), or cobalt-iron-nickel (CoFeNi).

The second magnetic structure MS2 may include the first free magnetic pattern FL1 provided on the tunnel barrier pattern TBR. In the present embodiment, the second magnetic structure MS2 may be configured to include a free magnetic pattern FL constituting the third type of magnetic tunnel junction MTJ3 shown in FIG. 3A. For example, the first free magnetic pattern FL1 may have a magnetization direction substantially parallel to the top surface of the substrate 100.

The first free magnetic pattern FL1 may be formed of a ferromagnetic material containing at least one of cobalt (Co), iron (Fe), or nickel (Ni). For example, the first free magnetic pattern FL1 may include at least one of CoFeB, CoFe, or CoFeNi.

The second pinned magnetic pattern PL2 may be provided adjacent to the magnetic tunnel junction MTJ. The second pinned magnetic pattern PL2 may include an in-plane magnetic material (for example, at least one of the above materials enumerated for the first pinned magnetic pattern PL1).

The second pinned magnetic pattern PL2 may have a second magnetization direction MD2 that is fixed. As an example, the first magnetization direction MD1 may be antiparallel to the second magnetization direction MD2. However, example embodiments of the inventive concepts may not be limited thereto, and for example, the first magnetization direction MD 1 may be parallel to the second magnetization direction MD2, as described with reference to FIG. 5C.

Referring to FIG. 5G, the second pinned magnetic pattern PL2 may have a second magnetization direction MD2 that is fixed. Unlike that of FIG. 5F, the second magnetization direction MD2 may be perpendicular to the first magnetization direction MD1 of the first pinned magnetic pattern PL1.

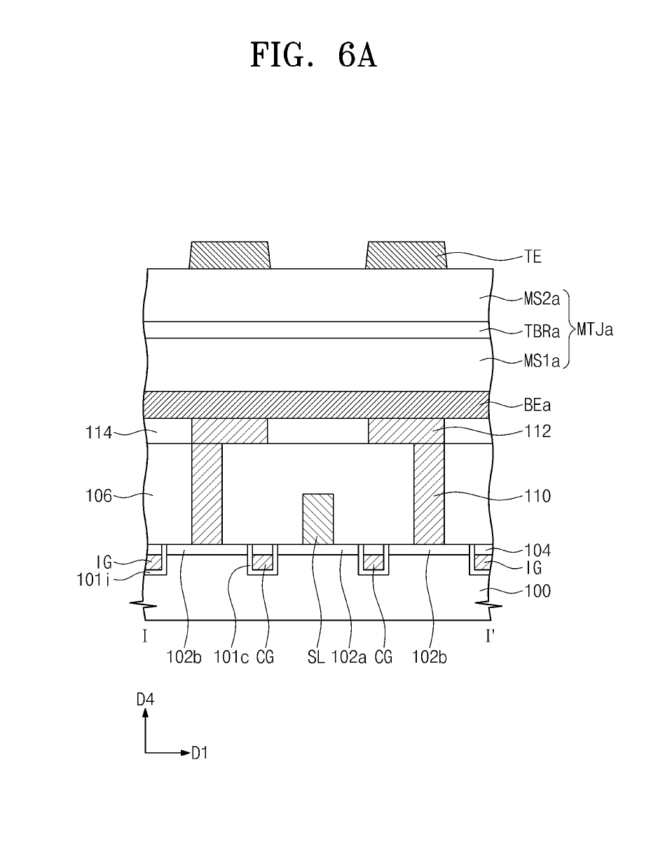

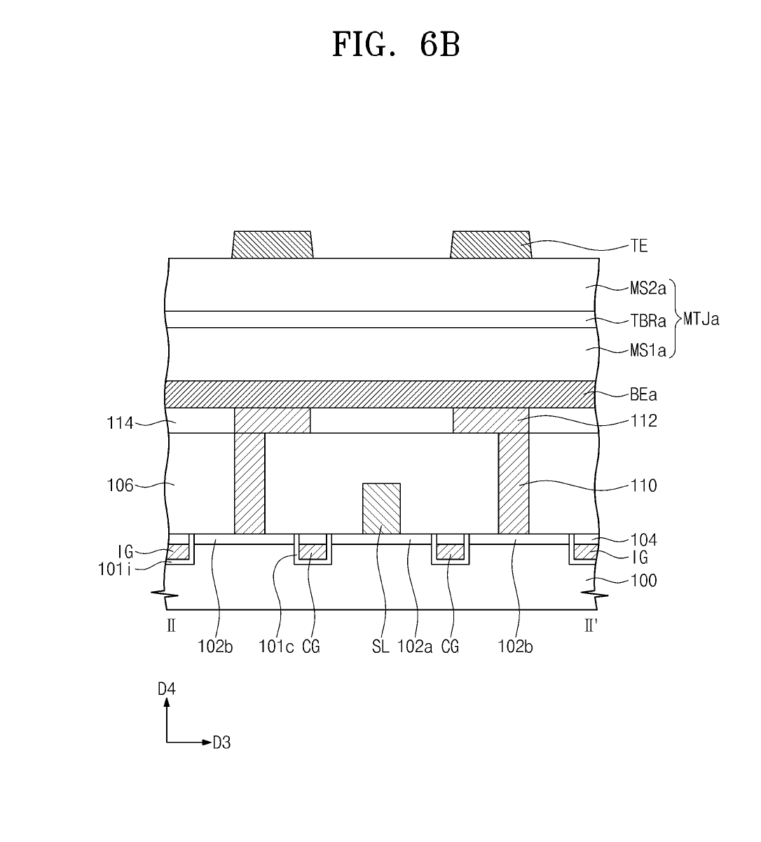

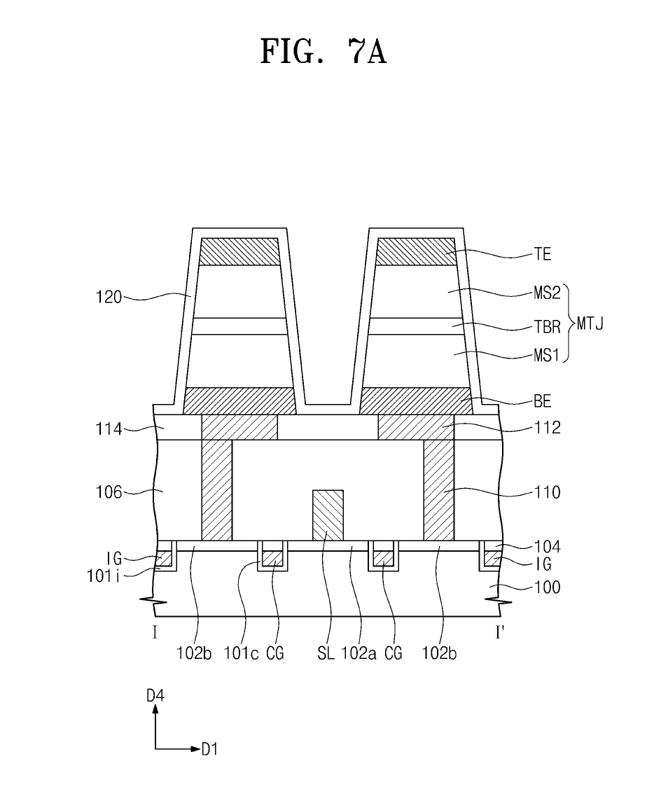

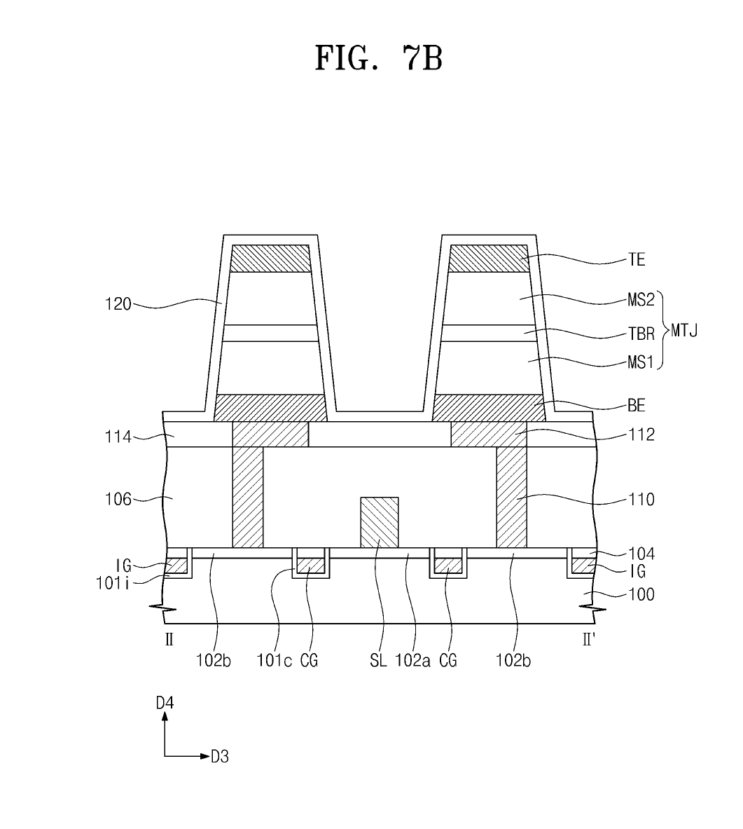

FIGS. 6A through 8A and 6B through 8B are sectional views illustrating a method of fabricating a magnetic memory device according to example embodiments of the inventive concepts. FIGS. 6A through 8A are sectional views taken along line I-I′ of FIG. 4A, and FIGS. 6B through 8B are sectional views taken along line II-II′ of FIG. 4A.

Referring to FIGS. 4A, 6A, and 6B, the selection devices may be formed on the substrate 100. The selection devices may be transistors. The transistors may include cell gate electrodes CG provided on the substrate 100. The cell gate electrodes CG may be spaced apart from each other in the first direction D1 and may be formed to extend in the second direction D2 or cross the first direction D1. The cell gate dielectric layers 101c may be respectively formed between the cell gate electrodes CG and the substrate 100.

The isolation gate electrodes IG may be formed spaced apart from each other with the pair of cell gate electrodes CG interposed therebetween. The isolation gate electrodes IG may be spaced apart from each other in the first direction D1 and may extend in the second direction D2. The isolation gate dielectric layers 101i may be respectively formed between the isolation gate electrodes IG and the substrate 100.

The formation of the cell and isolation gate electrodes CG and IG may include forming gate recess regions. The gate recess regions may be formed in the substrate 100 to be spaced apart from each other in the first direction D1 and extend in the second direction D2. Thereafter, the cell and isolation gate dielectric layers 101c and 101i and the cell and isolation gate electrodes CG and IG may be formed to fill the gate recess regions.

The gate hard mask patterns 104 may be respectively formed on the cell and isolation gate electrodes CG and IG. The gate hard mask patterns 104 may be formed to fill the remaining empty spaces of the gate recess regions. A planarization process may be performed on the gate hard mask patterns 104, and as a result of the planarization process, the gate hard mask patterns 104 may be formed to have top surfaces substantially coplanar with that of the substrate 100.

The cell gate electrodes CG may include at least one of, for example, doped semiconductor materials (e.g., doped silicon), metals (e.g., tungsten, aluminum, titanium, and/or tantalum), conductive metal nitrides (e.g., titanium nitride, tantalum nitride, and/or tungsten nitride), or metal-semiconductor compounds (e.g., metal silicide). The isolation gate electrodes IG may include the same material as the cell gate electrodes CG. The cell gate dielectric layers 101c and the isolation gate dielectric layers 101i may include, for example, at least one of oxide (e.g., silicon oxide), nitride (e.g., silicon nitride), oxynitride (e.g., silicon oxynitride), and/or a high-k dielectric (e.g., insulating metal oxides such as hafnium oxide or aluminum oxide). The gate hard mask patterns 104 may include at least one of oxide (e.g., silicon oxide), nitride (e.g., silicon nitride), or oxynitride (e.g., silicon oxynitride).

The first and second impurity regions 102a and 102b may be formed at both sides of each of the cell gate electrodes CG. The first and second impurity regions 102a and 102b may be doped to have a different conductivity type from that of the substrate 100.

The source line SL may be formed on the substrate 100 between the pair of cell gate electrodes CG. The source line SL may be formed to be electrically connected to the first impurity region 102a between the pair of cell gate electrodes CG. The source line SL may include at least one of, for example, doped semiconductor materials (e.g., doped silicon), metals (e.g., tungsten, aluminum, titanium, and/or tantalum), conductive metal nitrides (e.g., titanium nitride, tantalum nitride, and/or tungsten nitride), or metal-semiconductor compounds (e.g., metal silicide).

The first interlayered insulating layer 106 may be formed on the substrate 100 to cover the cell and isolation gate electrodes CG and IG and the source line SL. The contacts 110 may be connected to the second impurity regions 102b through the first interlayered insulating layer 106. As an example, the first interlayered insulating layer 106 may be a silicon oxide layer, which may be formed by a chemical vapor deposition. The contacts 110 may be formed in such a way that each of them is connected to a corresponding one of the second impurity regions 102b, which are disconnected from the source line SL. The contacts 110 may include at least one of metals, conductive metal nitrides, or doped semiconductor materials.

The buried insulating layer 114 may be formed on the first interlayered insulating layer 106, and the conductive pads 112 may be formed through the buried insulating layer 114 and may be connected to the contacts 110, respectively. As an example, the buried insulating layer 114 may include a silicon nitride layer, which may be formed by a chemical vapor deposition. The conductive pads 112 may include at least one of metals, conductive metal nitrides, or doped semiconductor materials. A planarization process may be performed on the conductive pads 112, and as a result of the planarization process, the conductive pads 112 may be formed to have top surfaces substantially coplanar with that of the buried insulating layer 114.

A bottom electrode layer BEa and a magnetic tunnel junction layer MTJa may be sequentially formed on the conductive pads 112 and the buried insulating layer 114. The bottom electrode layer BEa may include at least one of metals, conductive metal nitrides, or doped semiconductor materials. The magnetic tunnel junction layer MTJa may include a first magnetic layer MS1a, a tunnel barrier layer TBRa, and a second magnetic layer MS2a sequentially deposited on the bottom electrode layer BEa. A metal mask layer may be formed on the magnetic tunnel junction layer MTJa and may be patterned to form the top electrodes TE. The metal mask layer may include at least one of metals, conductive metal nitrides, or doped semiconductor materials. An ion beam etching process or a dry etching process may be performed to form the top electrodes TE. The top electrodes TE may be formed to be overlapped with the conductive pads 112, respectively, when viewed in plan view.

Referring to FIGS. 4A, 7A, and 7B, the magnetic tunnel junction layer MTJa and the bottom electrode layer BEa may be patterned using the top electrodes TE as an etch mask to form the magnetic tunnel junctions MTJ and the bottom electrodes BE.

The magnetic tunnel junctions MTJ may include the first magnetic structures MS1 respectively connected to the bottom electrodes BE, the second magnetic structures MS2 respectively connected to the top electrodes TE, and the tunnel barrier patterns TBR disposed between the first and second magnetic structures MS1 and MS2. The magnetic tunnel junctions MTJ may be formed to be spaced apart from each other in the first and second directions D1 and D2, when viewed in plan view. The magnetic tunnel junctions MTJ may be formed to be overlapped with the conductive pads 112, respectively.

After the formation of the magnetic tunnel junctions MTJ, the capping layer 120 may be formed on the magnetic tunnel junctions MTJ. The capping layer 120 may be formed to cover sidewalls of the magnetic tunnel junctions MTJ and the bottom electrodes BE and a top surface of the buried insulating layer 114. The capping layer 120 may be formed of or include a metal oxide layer, which may be formed by a chemical vapor deposition process.

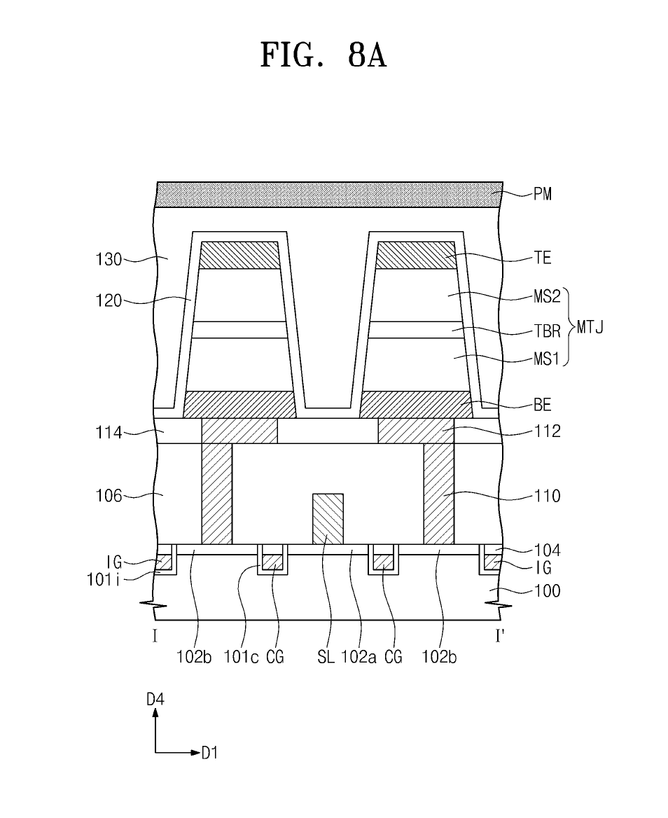

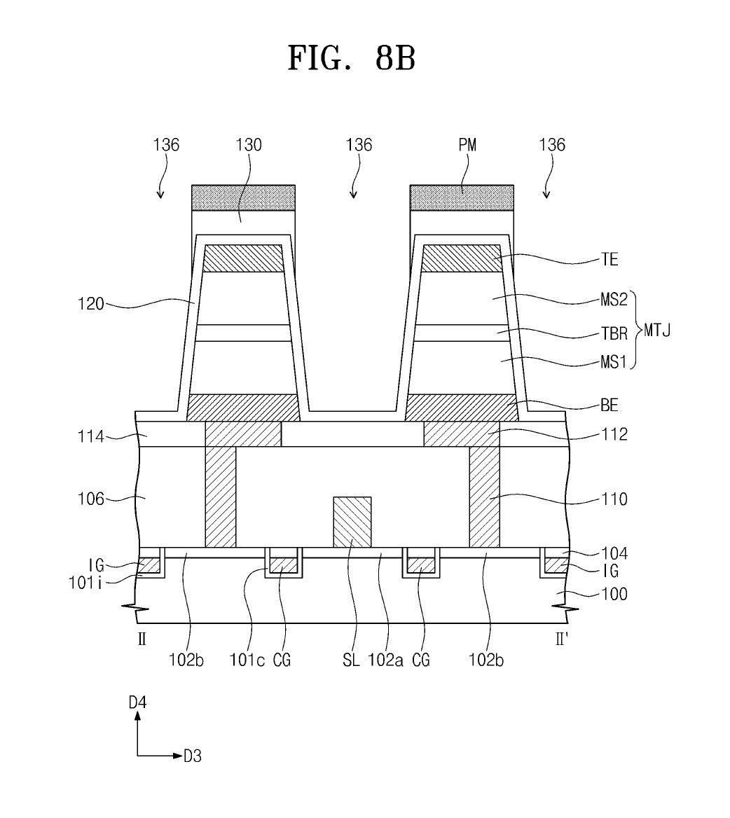

Referring to FIGS. 4A, 8A, and 8B, the second interlayered insulating layer 130 may be formed on the capping layer 120. The second interlayered insulating layer 130 may be formed of or include, for example, a silicon oxide layer. A photomask PM may be formed on the second interlayered insulating layer 130 to have openings. The openings may be formed to be overlapped with the second pinned magnetic pattern PL2 of FIG. 4A. The second interlayered insulating layer 130 may be etched using the photomask PM as an etch mask to form holes 136 penetrating the second interlayered insulating layer 130. The holes 136 may be formed to expose regions between the magnetic tunnel junctions. The photomask PM may be removed after the formation of the holes 136.

Referring back to FIGS. 4A through 4C, the separation structures SS may be formed to fill the holes 136. Each of the separation structures SS may include a second pinned magnetic pattern PL2 and a first insulating pattern 135, which are sequentially stacked on the capping layer 120.

A magnetic material may be deposited in the holes 136 to form the second pinned magnetic patterns PL2. The second pinned magnetic patterns PL2 may be formed to fill lower portions of the holes 136. When viewed in plan view, the second pinned magnetic patterns PL2 may be arranged two-dimensionally (i.e., spaced apart from each other in the first and second directions D1 and D2). In addition, the magnetic tunnel junctions MTJ and the second pinned magnetic patterns PL2 may be alternatingly arranged in the third direction D3. The third direction D3 may be a direction crossing both of the first and second directions D1 and D2 and being parallel to the top surface of the substrate 100.

An insulating layer (not shown) may be formed to fill upper portions of the holes 136. The insulating layer may be formed of or include, for example, a silicon oxide layer. The insulating layer may be formed to fill the holes 136 and cover the second interlayered insulating layer 130.

Thereafter, the insulating layer and the second interlayered insulating layer 130 may be planarized to form the first insulating patterns 135 exposing the top electrodes TE. The planarization process may be performed to remove the capping layer 120 remaining on the top surfaces of the top electrodes TE. As a result of the planarization process, the top electrodes TE may have top surfaces substantially coplanar with those of the second interlayered insulating layer 130 and the first insulating patterns 135.

The third interlayered insulating layer 140 may be formed on the second interlayered insulating layer 130. Thereafter, the bit lines BL may be formed in the third interlayered insulating layer 140. When viewed in plan view, the bit lines BL may be spaced apart from each other in the second direction D2 and extend in the first direction D1. Each of the bit lines BL may be coupled to a plurality of the top electrodes TE arranged parallel to the first direction D1. The bit lines BL may be formed of or include, for example, at least one of metals or conductive metal nitrides.

### Magnetic Memory Device

### Other Example Embodiments

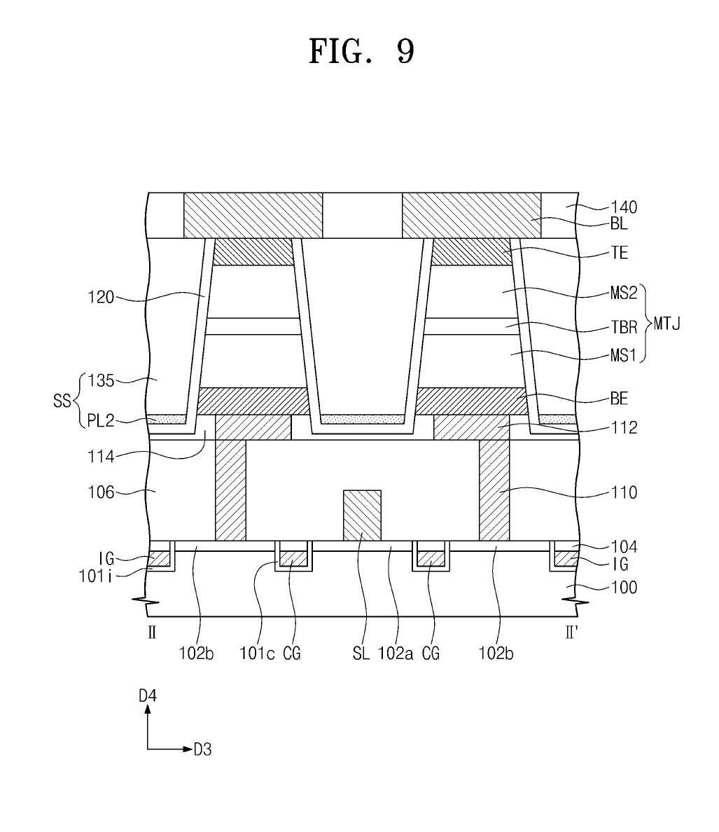

FIG. 9 is a sectional view taken along line II-II′ of FIG. 4A to illustrate a magnetic memory device according to other example embodiments of the inventive concepts. In the following description of FIG. 9, an element previously described with reference to FIGS. 4A through 4C may be identified by a similar or identical reference number without repeating an overlapping description thereof, for the sake of brevity.

Referring to FIGS. 4A, 4B, and 9, recess regions may be defined in the buried insulating layer 114. Unlike that described with reference to FIG. 4C, the recess region may be provided between a pair of the magnetic tunnel junctions MTJ spaced apart from each other in the third direction D3. However, as described with reference to FIG. 4B, the recess region may not be defined between a pair of the magnetic tunnel junctions MTJ spaced apart from each other in the first direction D1.

The second pinned magnetic patterns PL2 may be provided to fill the recess regions. For example, the recess regions may be completely filled with the capping layer 120 and the second pinned magnetic pattern PL2. The second pinned magnetic patterns PL2 may be formed to have bottom surfaces in direct contact with the capping layer 120. The second pinned magnetic patterns PL2 may have top surfaces substantially coplanar with that of the buried insulating layer 114.

In the present embodiment, the first insulating patterns 135 and the second interlayered insulating layer 130 may be formed by the same process and may be continuously connected to each other to constitute a single insulating layer. Except for the difference described above, the magnetic memory device according to the present embodiment may be the same as that described with reference to FIGS. 4A through 4C.

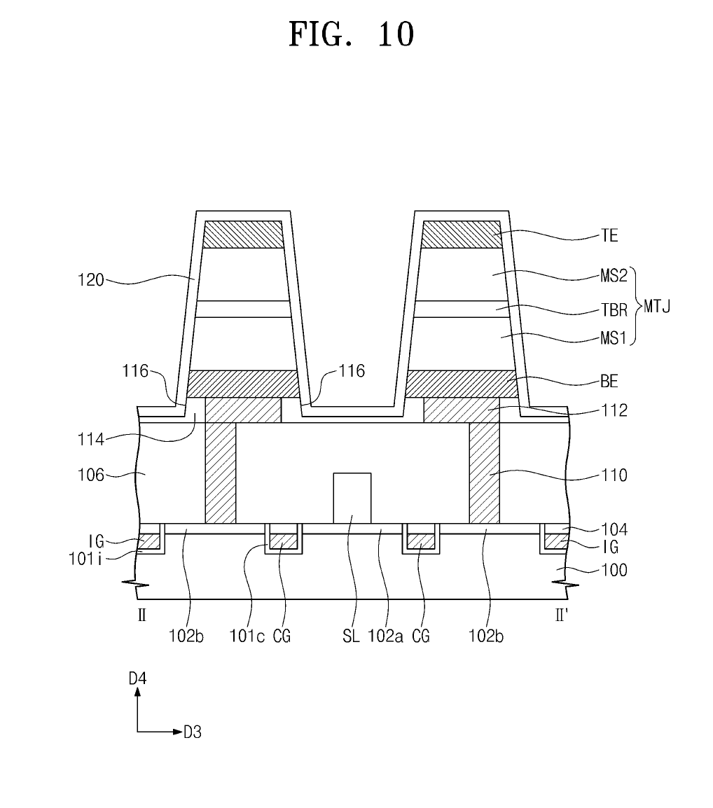

FIG. 10 is a sectional view taken along line II-II′ of FIG. 4A to illustrate a method of fabricating a magnetic memory device according to other example embodiments of the inventive concepts. In the following description of FIG. 10, an element or step previously described with reference to FIGS. 6A through 8B may be identified by a similar or identical reference number without repeating an overlapping description thereof, for the sake of brevity.

Referring to FIGS. 4A, 7A, and 10, a patterning process may be performed on the resulting structure described with reference to FIGS. 4A, 6A, and 6B. For example, in the patterning process, the magnetic tunnel junction layer MTJa and the bottom electrode layer BEa may be patterned using the top electrodes TE as an etch mask to form the magnetic tunnel junctions MTJ and the bottom electrodes BE.

Referring to FIG. 4A, a distance between a pair of the magnetic tunnel junctions MTJ spaced apart from each other in the third direction D3 may be greater than that in the first direction D1. Accordingly, when viewed along the third direction D3, a region between the magnetic tunnel junctions MTJ may be over-etched during the patterning process. As a result of such an over etching, the recess region may be extended into the buried insulating layer 114 between the magnetic tunnel junctions MTJ.

After the formation of the magnetic tunnel junctions MTJ, the capping layer 120 may be formed on the magnetic tunnel junctions MTJ. The capping layer 120 may be formed to cover side and bottom surfaces of the recess regions. The level of the top surface of the capping layer 120 may be lower in the recess regions than between a pair of the magnetic tunnel junctions MTJ separated from each other in the first direction D1.

Referring back to FIGS. 4A, 4B, and 9, the second pinned magnetic patterns PL2 may be formed to fill lower portions of the recess regions. For example, a magnetic layer may be deposited on the capping layer 120 and may be etched back. As a result, the second pinned magnetic patterns PL2 may be locally formed in the recess regions. As described above, the top surface of the capping layer 120 may be lower in the recess regions than in neighboring regions. Thus, the magnetic layer may be locally formed in only the recess regions, after the etch-back process.

The etch-back process may be performed in such a way that each of the second pinned magnetic patterns PL2 is formed, in a self-aligned manner, between the pair of magnetic tunnel junctions MTJ separated from each other in the third direction D3. In other words, when viewed in plan view, the magnetic tunnel junctions MTJ and the second pinned magnetic patterns PL2 may be alternatingly arranged along the third direction D3.

Next, the second interlayered insulating layer 130, the third interlayered insulating layer 140, and the bit lines BL may be formed. According to the present embodiment, the second interlayered insulating layer 130 may include portions, which are positioned on the second pinned magnetic patterns PL2 and are used as the first insulating patterns 135. Except for the difference described above, the magnetic memory device according to the present embodiment may be the same as that described with reference to FIGS. 4A through 4C.

### Magnetic Memory Device

### Still Other Example Embodiments

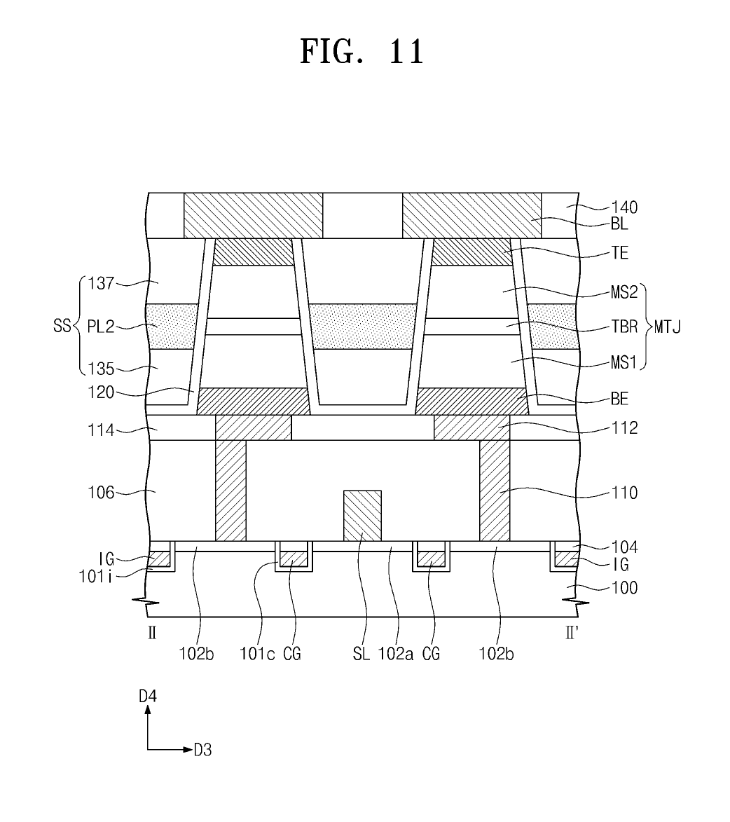

FIG. 11 is a sectional view taken along line II-II′ of FIG. 4A to illustrate a magnetic memory device according to still other example embodiments of the inventive concepts. In the following description of FIG. 11, an element previously described with reference to FIGS. 4A through 4C may be identified by a similar or identical reference number without repeating an overlapping description thereof, for the sake of brevity.

Referring to FIGS. 4A, 4B, and 11, the separation structures SS may be interposed between the magnetic tunnel junctions MTJ. Each of the separation structures SS may include the first insulating pattern 135, the second pinned magnetic pattern PL2, and a second insulating pattern 137, which are sequentially stacked on the substrate 100. In other words, the second pinned magnetic patterns PL2 may be interposed between the first insulating patterns 135 and the second pinned magnetic patterns PL2.

As an example, top surfaces of the second pinned magnetic patterns PL2 may be positioned at a lower level than those of the magnetic tunnel junctions MTJ, and bottom surfaces of the second pinned magnetic patterns PL2 may be positioned at a higher level than those of the magnetic tunnel junctions MTJ. Except for the difference described above, the magnetic memory device according to the present embodiment may be the same as that described with reference to FIGS. 4A through 4C.

The following is a description of a method for fabricating a magnetic memory device, according to the present embodiment. Description of an element or step previously described with reference to FIGS. 6A through 8B may be omitted, for the sake of brevity.

Referring back to FIGS. 4A, 4B, and 11, the separation structures SS may be formed to fill the holes 136 on the resulting structure described with reference to FIGS. 4A, 8A, and 8B. Each of the separation structures SS may include the first insulating pattern 135, the second pinned magnetic pattern PL2, and a second insulating pattern 137, which are sequentially stacked on the substrate 100.

For example, an insulating layer may be deposited to form the first insulating patterns 135 in lower portions of the holes 136. Thereafter, a magnetic material may be deposited on the first insulating patterns 135 to form the second pinned magnetic pattern PL2. Another insulating layer may be deposited on the second pinned magnetic patterns PL2 to form the second insulating pattern 137. The formation of the separation structures SS may further include a planarization process, which is performed on another insulating layer to expose the top electrodes TE.

### Magnetic Memory Device

### Even Other Example Embodiments

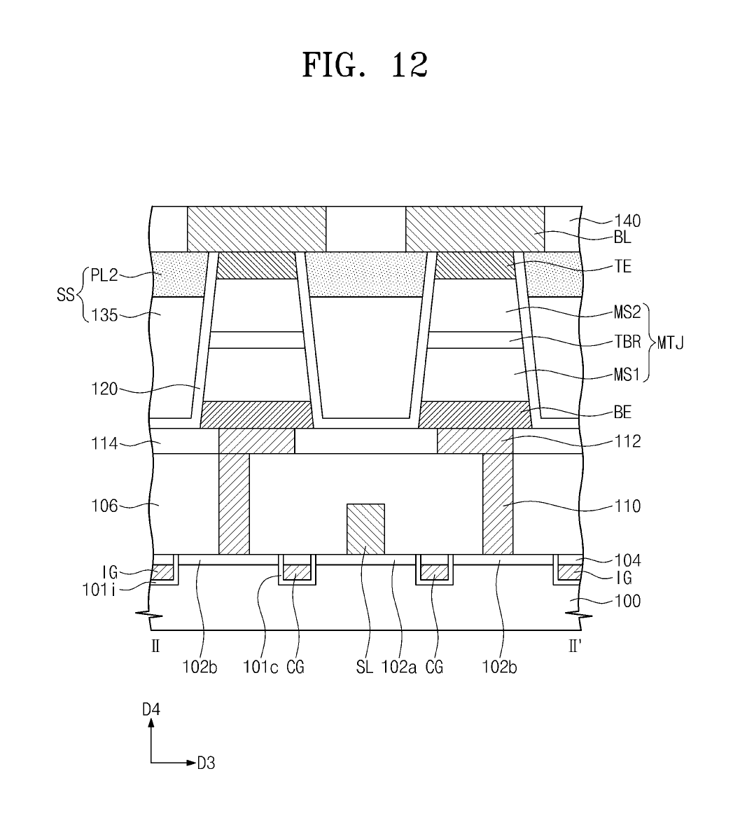

FIG. 12 is a sectional view taken along line II-II′ of FIG. 4A to illustrate a magnetic memory device according to even other example embodiments of the inventive concepts. In the following description of FIG. 12, an element previously described with reference to FIGS. 4A through 4C may be identified by a similar or identical reference number without repeating an overlapping description thereof, for the sake of brevity.

Referring to FIGS. 4A, 4B, and 12, the separation structures SS may be interposed between the magnetic tunnel junctions MTJ. Each of the separation structures SS may include the first insulating pattern 135 and the second pinned magnetic pattern PL2, which are sequentially stacked on the substrate 100. In other words, the second pinned magnetic patterns PL2 may be vertically separated from the substrate 100 with the first insulating patterns 135 interposed therebetween.

As an example, the second pinned magnetic patterns PL2 may have bottom surfaces positioned at a higher level than those of the magnetic tunnel junctions MTJ. The second pinned magnetic patterns PL2 may have top surfaces substantially coplanar with those of the top electrodes TE. Except for the difference described above, the magnetic memory device according to the present embodiment may be the same as that described with reference to FIGS. 4A through 4C.

The following is a description of a method for fabricating a magnetic memory device, according to the present embodiment. Description of an element or step previously described with reference to FIGS. 6A through 8B may be omitted, for the sake of brevity.

Referring back to FIGS. 4A, 4B, and 12, the separation structures SS may be formed to fill the holes 136 on the resulting structure described with reference to FIGS. 4A, 8A, and 8B. Each of the separation structures SS may include the first insulating pattern 135 and the second pinned magnetic pattern PL2, which are sequentially stacked on the substrate 100.

For example, an insulating layer may be deposited to form the first insulating patterns 135 in lower portions of the holes 136. Thereafter, a magnetic material may be deposited on the first insulating patterns 135 to form the second pinned magnetic pattern PL2. Here, the formation of the separation structures SS may further include a planarization process, which is performed on the magnetic material to expose the top electrodes TE.

### Magnetic Memory Device

### Yet Other Example Embodiments

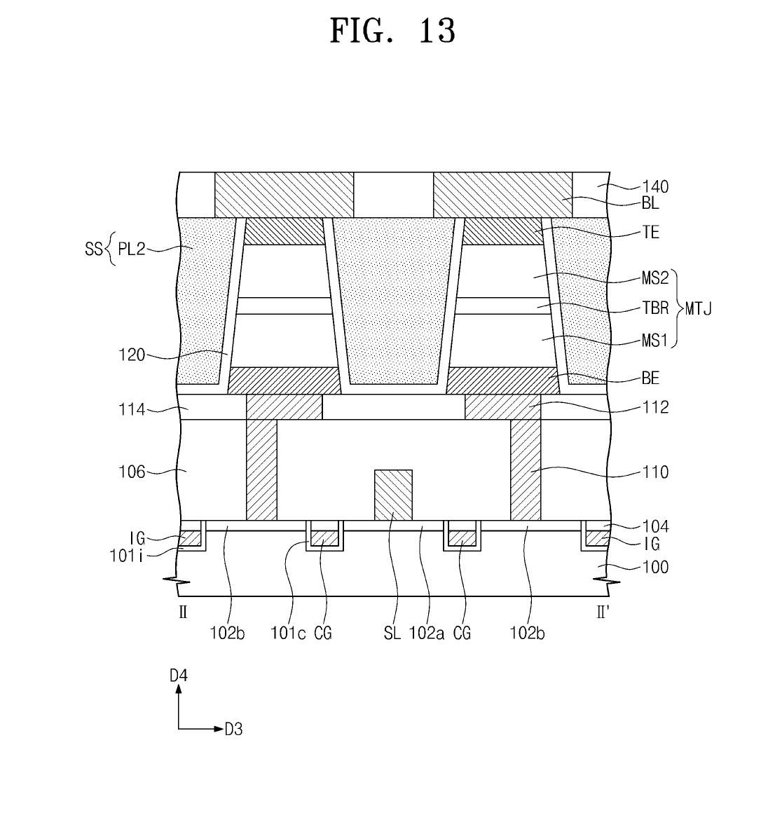

FIG. 13 is a sectional view taken along line II-II′ of FIG. 4A to illustrate a magnetic memory device according to yet other example embodiments of the inventive concepts. In the following description of FIG. 13, an element previously described with reference to FIGS. 4A through 4C may be identified by a similar or identical reference number without repeating an overlapping description thereof, for the sake of brevity.

Referring to FIGS. 4A, 4B, and 13, the separation structures SS may be interposed between the magnetic tunnel junctions MTJ. Each of the separation structures SS may include or consist of the second pinned magnetic pattern PL2. For example, the separation structures SS may have only the second pinned magnetic patterns PL2.

As an example, bottom surfaces of the second pinned magnetic patterns PL2 may be positioned at a lower level than those of the magnetic tunnel junctions MTJ, and top surfaces of the second pinned magnetic patterns PL2 may be positioned at a higher level than those of the magnetic tunnel junctions MTJ. Further, the top surfaces of the second pinned magnetic patterns PL2 may be substantially coplanar with those of the top electrodes TE. Except for the difference described above, the magnetic memory device according to the present embodiment may be the same as that described with reference to FIGS. 4A through 4C.

The following is a description of a method for fabricating a magnetic memory device, according to the present embodiment. Description of an element or step previously described with reference to FIGS. 6A through 8B may be omitted, for the sake of brevity.

Referring back to FIGS. 4A, 4B, and 11, the separation structures SS may be formed to fill the holes 136 on the resulting structure described with reference to FIGS. 4A, 8A, and 8B. Each of the separation structures SS may include or consist of the second pinned magnetic pattern PL2.

The formation of the second pinned magnetic patterns PL2 may include depositing a magnetic material to fill the whole region of the holes 136 and then planarizing the magnetic material to expose the top electrodes TE.

### Magnetic Memory Device

### Further Example Embodiments

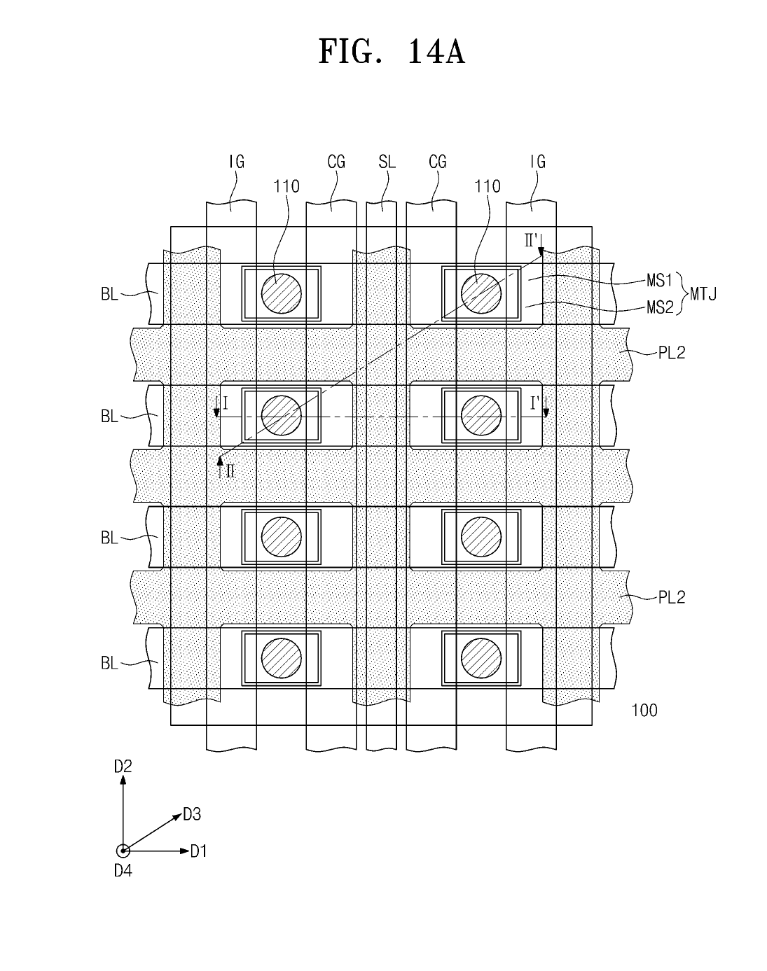

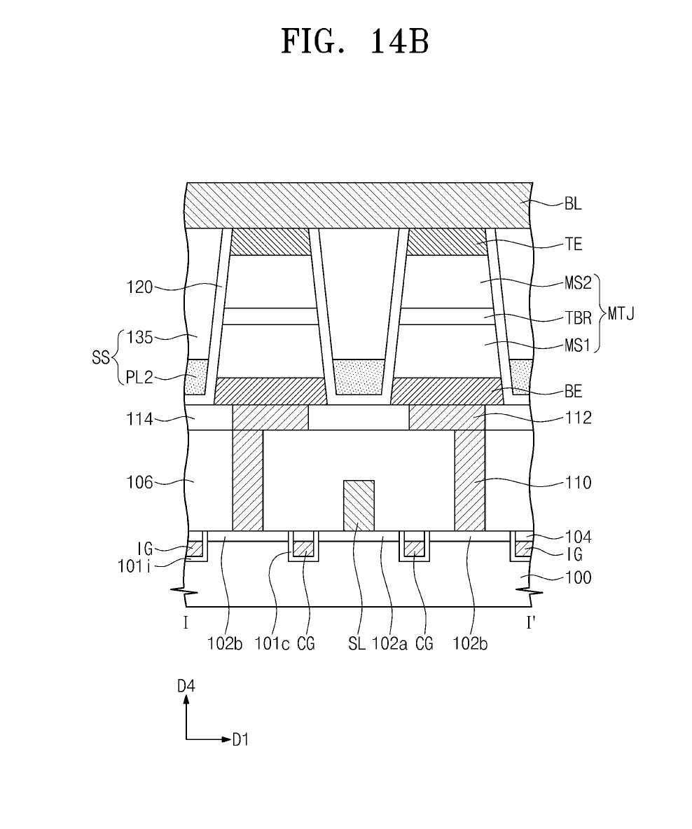

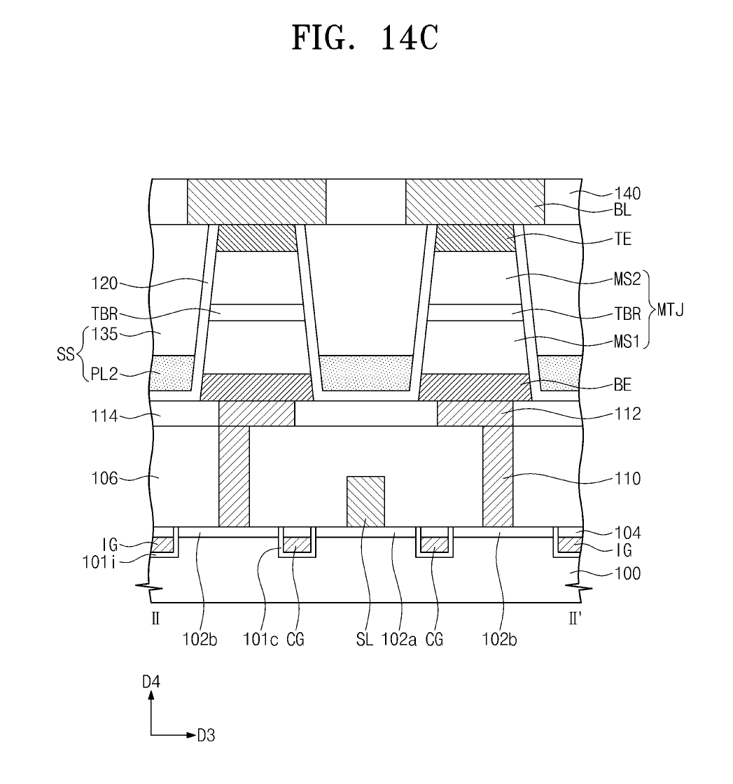

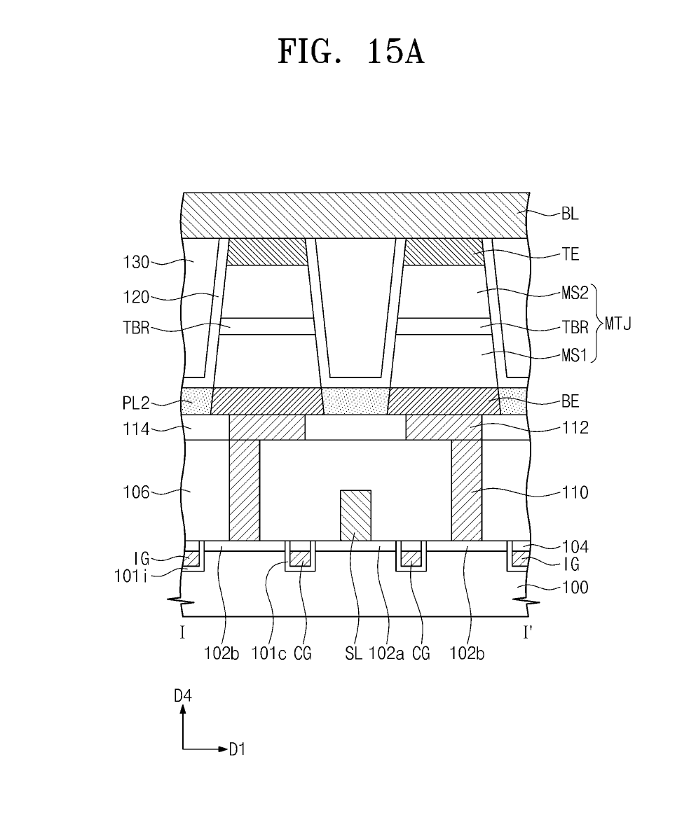

FIG. 14A is a plan view of a magnetic memory device according to further example embodiments of the inventive concepts. FIG. 14B is a sectional view taken along line I-I′ of FIG. 14A, and FIG. 14C is a sectional view taken along line II-II′ of FIG. 14A. In the following description of FIGS. 14A through 14C, an element previously described with reference to FIGS. 4A through 4C may be identified by a similar or identical reference number without repeating an overlapping description thereof, for the sake of brevity.

Referring to FIGS. 14A through 14C, the separation structure SS may be interposed between the magnetic tunnel junctions MTJ. The separation structure SS may include the second pinned magnetic pattern PL2 and the first insulating pattern 135, which are sequentially stacked on the substrate 100. Unlike that previously described with reference to FIGS. 4A through 4C, the separation structure SS according to the present embodiment may be a single pattern, which is continuously extended to fill gap regions between the magnetic tunnel junctions MTJ. In other words, when viewed in plan view, the separation structure SS may extend in between the magnetic tunnel junctions MTJ and thereby enclose each of the magnetic tunnel junctions MTJ. Accordingly, as illustrated in the section of FIG. 14B taken along the first direction D1, the second pinned magnetic pattern PL2 may be provided between the magnetic tunnel junctions MTJ.

Unlike that described with reference to FIGS. 4A through 4C, the second interlayered insulating layer 130 according to the present embodiment may be omitted, and the first insulating pattern 135 may be provided to fill an empty space between the magnetic tunnel junctions MTJ. Except for the difference described above, the magnetic memory device according to the present embodiment may be the same as that described with reference to FIGS. 4A through 4C.

The following is a description of a method for fabricating a magnetic memory device, according to the present embodiment. Description of an element or step previously described with reference to FIGS. 6A through 8B may be omitted, for the sake of brevity.

Referring back to FIGS. 14A through 14C, a magnetic material may be deposited on the resulting structure described with reference to FIGS. 4A, 7A, and 7B. Thereafter, an etch-back process may be performed on the magnetic material deposited, and thus, the second pinned magnetic pattern PL2 may be formed between the magnetic tunnel junctions MTJ (e.g., in lower portions of the gap regions between the magnetic tunnel junctions MTJ). When viewed in plan view, the second pinned magnetic patterns PL2 may be provided to enclose each of the magnetic tunnel junctions MTJ.

Next, an insulating layer may be formed to cover the second pinned magnetic pattern PL2, the magnetic tunnel junctions MTJ, and the capping layer 120. Thereafter, the insulating layer may be planarized to form the first insulating pattern 135 exposing the top electrodes TE. When viewed in plan view, the first insulating pattern 135 may be provided to enclose each of the magnetic tunnel junctions MTJ, like the second pinned magnetic pattern PL2. The second pinned magnetic pattern PL2 and the first insulating pattern 135 may constitute the separation structure SS.

The third interlayered insulating layer 140 may be formed on the first insulating pattern 135. The bit lines BL may be formed in the third interlayered insulating layer 140. Except for the difference described above, the magnetic memory device according to the present embodiment may be the same as that described with reference to FIGS. 4A through 4C.

### Magnetic Memory Device

### Still Further Example Embodiment

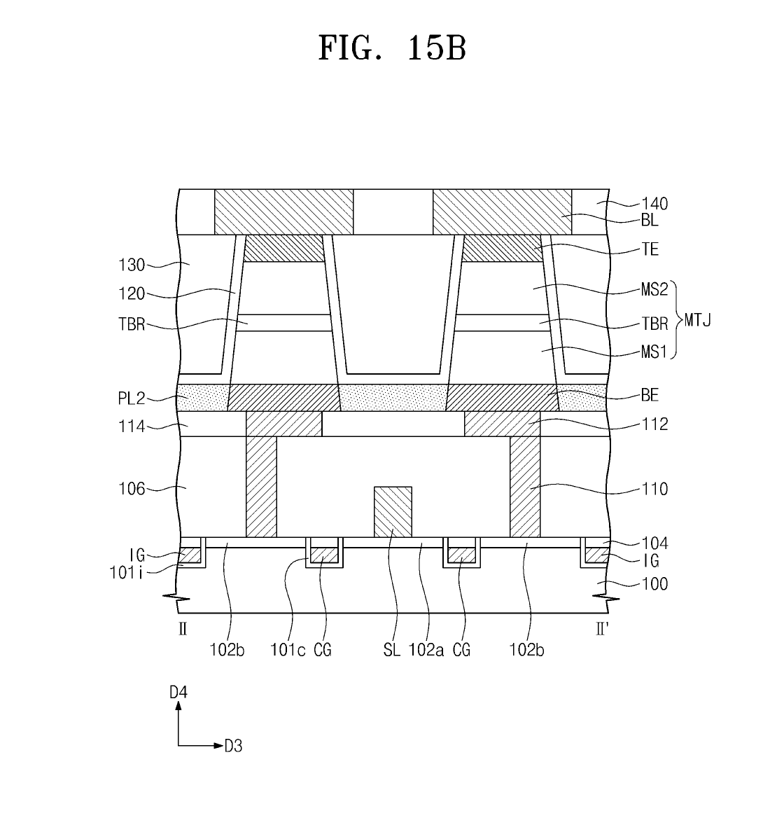

FIGS. 15A and 15B are sectional views illustrating a magnetic memory device according to still further example embodiments of the inventive concepts. FIG. 15A is a sectional view taken along line I-I′ of FIG. 14A, and FIG. 15B is a sectional view taken along line II-II′ of FIG. 14A. In the following description of FIGS. 15A and 15B, an element previously described with reference to FIGS. 4A through 4C may be identified by a similar or identical reference number without repeating an overlapping description thereof, for the sake of brevity.

Referring to FIGS. 14A, 15A, and 15B, the second pinned magnetic pattern PL2 may be provided between the bottom electrodes BE. For example, the second pinned magnetic pattern PL2 may be provided to fill gap regions between the bottom electrodes BE. The second pinned magnetic pattern PL2 may have a top surface substantially coplanar with those of the bottom electrodes BE, and the second pinned magnetic pattern PL2 may have a bottom surface substantially coplanar with those of the bottom electrodes BE. Furthermore, the second pinned magnetic pattern PL2 may have side surfaces in direct contact with those of the bottom electrodes BE. A bather layer (not shown) may be interposed between the second pinned magnetic pattern PL2 and the bottom electrodes BE, but example embodiments of the inventive concepts may not be limited thereto.

Unlike that described with reference to FIGS. 4A through 4C, when viewed in plan view, the second pinned magnetic pattern PL2 according to the present embodiment may be a single pattern extending in between the magnetic tunnel junctions MTJ. Further, the second pinned magnetic pattern PL2 may not be overlapped with the magnetic tunnel junctions MTJ, when viewed in a plan view.

The capping layer 120 may be provided to cover the side surfaces of the magnetic tunnel junctions MTJ. Further, the capping layer 120 may be extended to cover the top surface of the second pinned magnetic pattern PL2.

The second interlayered insulating layer 130 may be provided on the capping layer 120 to fill the gap regions between the magnetic tunnel junctions MTJ. The second interlayered insulating layer 130 may have a top surface substantially coplanar with those of the top electrodes TE. Except for this difference, the magnetic memory device according to the present embodiment may be the same as that described with reference to FIGS. 4A through 4C.

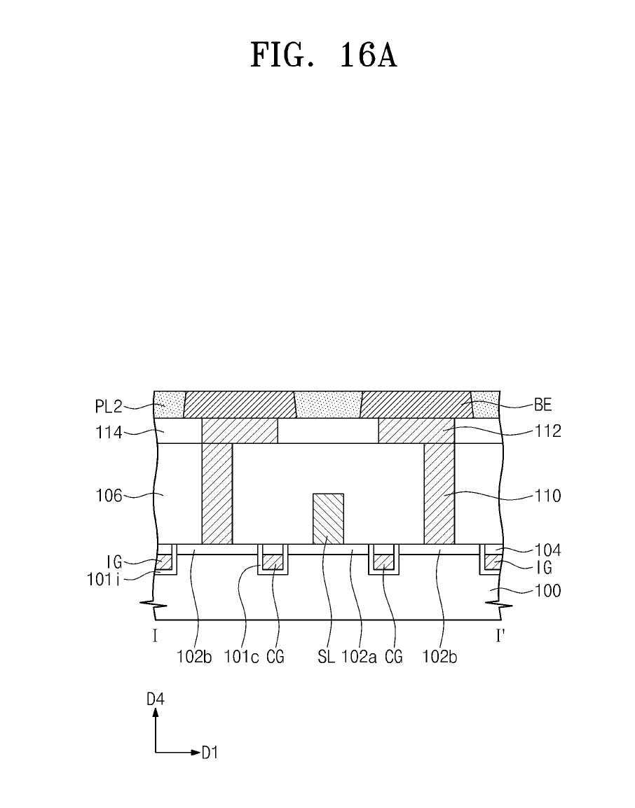

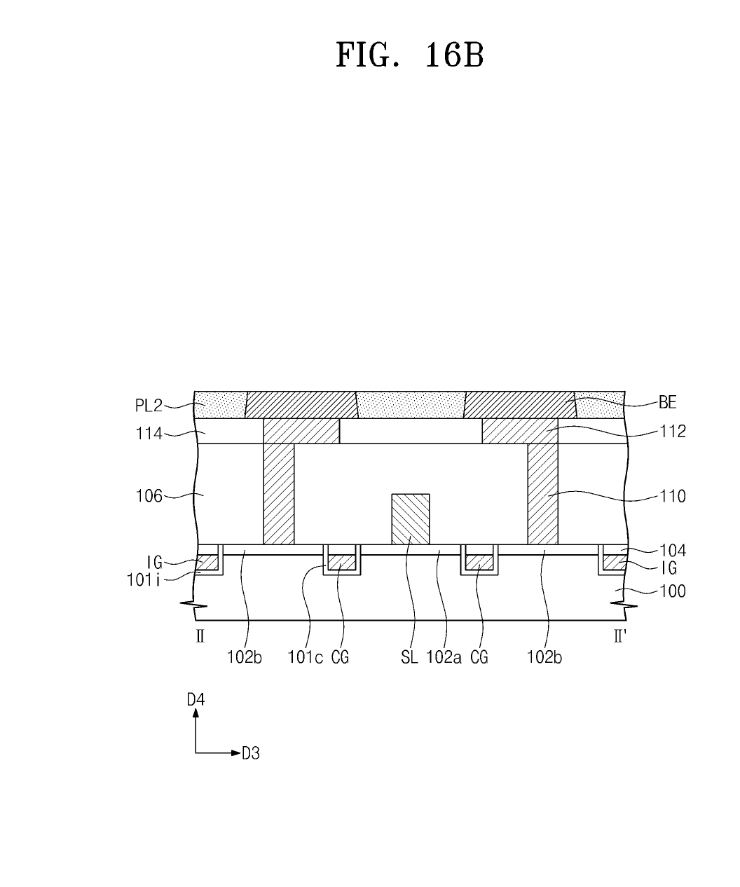

FIGS. 16A through 18B are sectional views illustrating a method of fabricating a magnetic memory device according to still further example embodiments of the inventive concepts. FIGS. 16A through 18A are sectional views taken along line I-I′ of FIG. 14A, and FIGS. 16B through 18B are sectional views taken along line II-II′ of FIG. 14A. In the following description of FIGS. 16A through 18B, an element previously described with reference to FIGS. 6A through 8B may be identified by a similar or identical reference number without repeating an overlapping description thereof, for the sake of brevity.

Referring to FIGS. 14A, 16A, and 16B, the bottom electrodes BE and the second pinned magnetic pattern PL2 may be formed on the conductive pads 112 and the buried insulating layer 114. The bottom electrodes BE may be formed by forming and then patterning a bottom electrode layer. The bottom electrodes BE may be formed to be overlapped with the magnetic tunnel junctions MTJ, which will be formed in a subsequent process, when viewed in a plan view.

A magnetic material may be deposited to fill a gap between the bottom electrodes BE. Thereafter, the magnetic material may be planarized to form the second pinned magnetic pattern PL2 exposing the bottom electrodes BE. Regions between the bottom electrodes BE may be filled with the second pinned magnetic pattern PL2, which is provided in the form of a single body. When viewed in plan view, the second pinned magnetic pattern PL2 may be provided to enclose each of the bottom electrodes BE. For example, the second pinned magnetic pattern PL2 may be shaped like a grating or mesh.

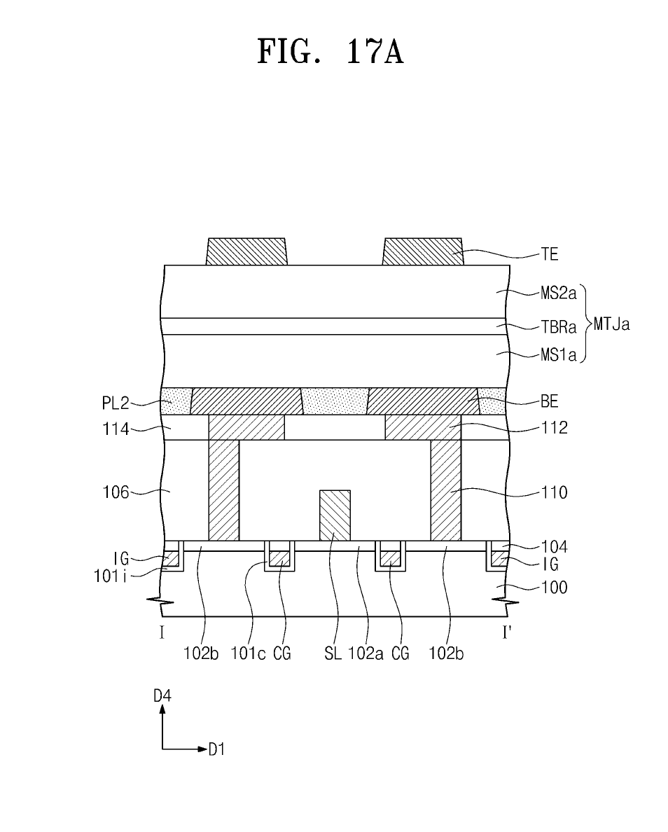

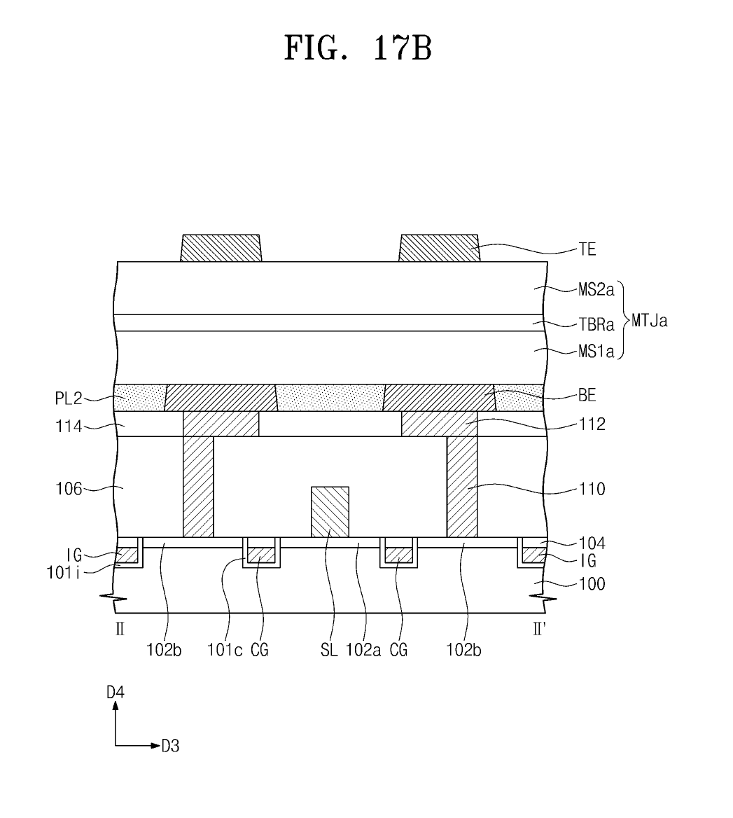

Referring to FIGS. 14A, 17A, and 17B, the magnetic tunnel junction layer MTJa may be formed on the bottom electrodes BE and the second pinned magnetic pattern PL2. The magnetic tunnel junction layer MTJa may include the first magnetic layer MS1a, the tunnel barrier layer TBRa, and the second magnetic layer MS2a, which are sequentially deposited on the bottom electrodes BE and the second pinned magnetic pattern PL2. Thereafter, the top electrodes TE may be formed on the magnetic tunnel junction layer MTJa.

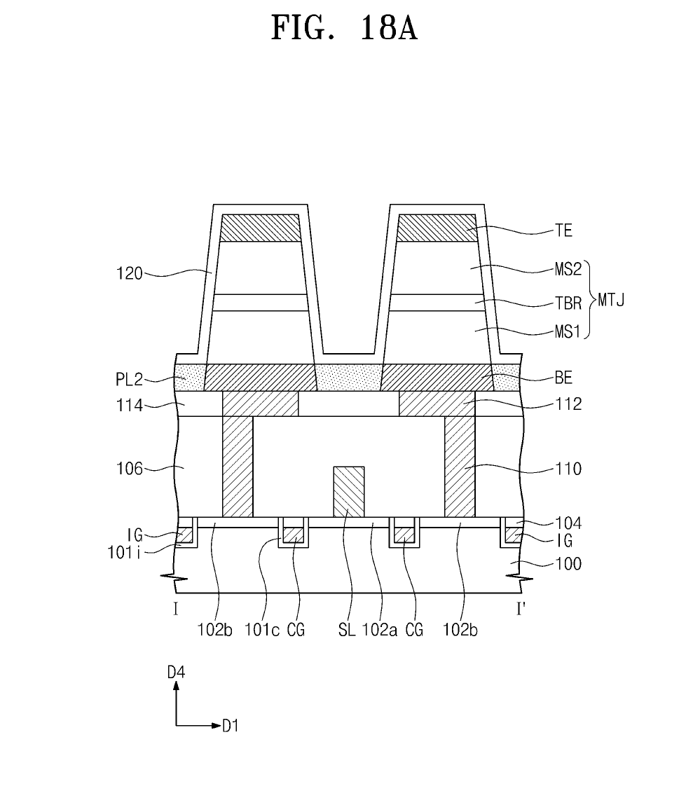

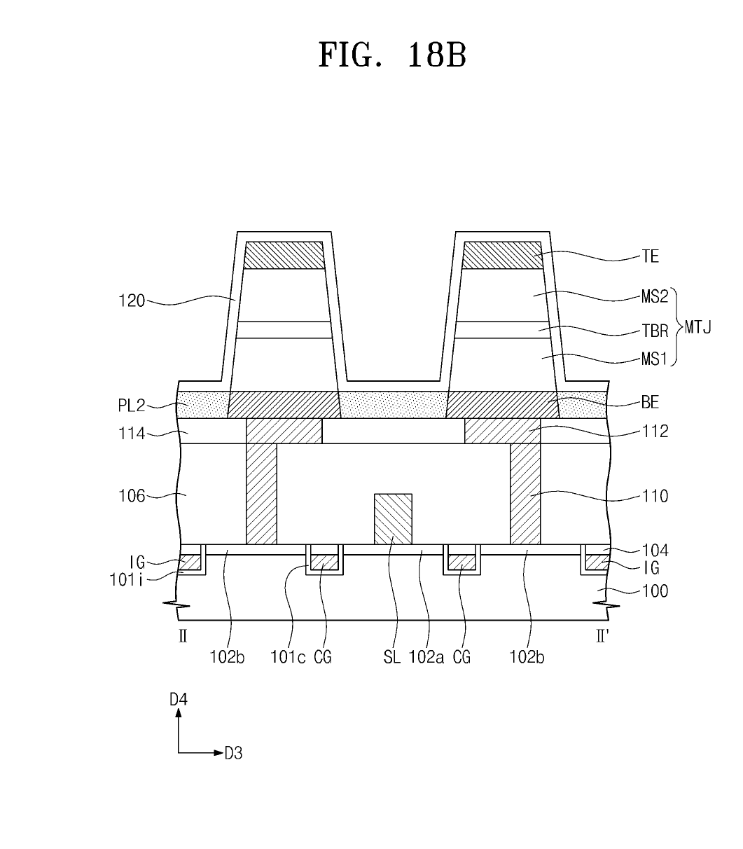

Referring to FIGS. 14A, 18A, and 18B, the magnetic tunnel junction layer MTJa may be patterned using the top electrodes TE as an etch mask to form the magnetic tunnel junctions MTJ. Next, the capping layer 120 may be formed on the magnetic tunnel junctions MTJ. The capping layer 120 may be formed to cover side surfaces of the magnetic tunnel junctions MTJ and may be extended to cover a top surface of the second pinned magnetic pattern PL2.

Referring back to FIGS. 14A, 15A, and 15B, the second interlayered insulating layer 130 may be formed on the capping layer 120. Next, the third interlayered insulating layer 140 may be formed on the second interlayered insulating layer 130. The bit lines BL may be formed in the third interlayered insulating layer 140. Except for this difference, the magnetic memory device according to the present embodiment may be the same as that described with reference to FIGS. 4A through 4C.

[Application]

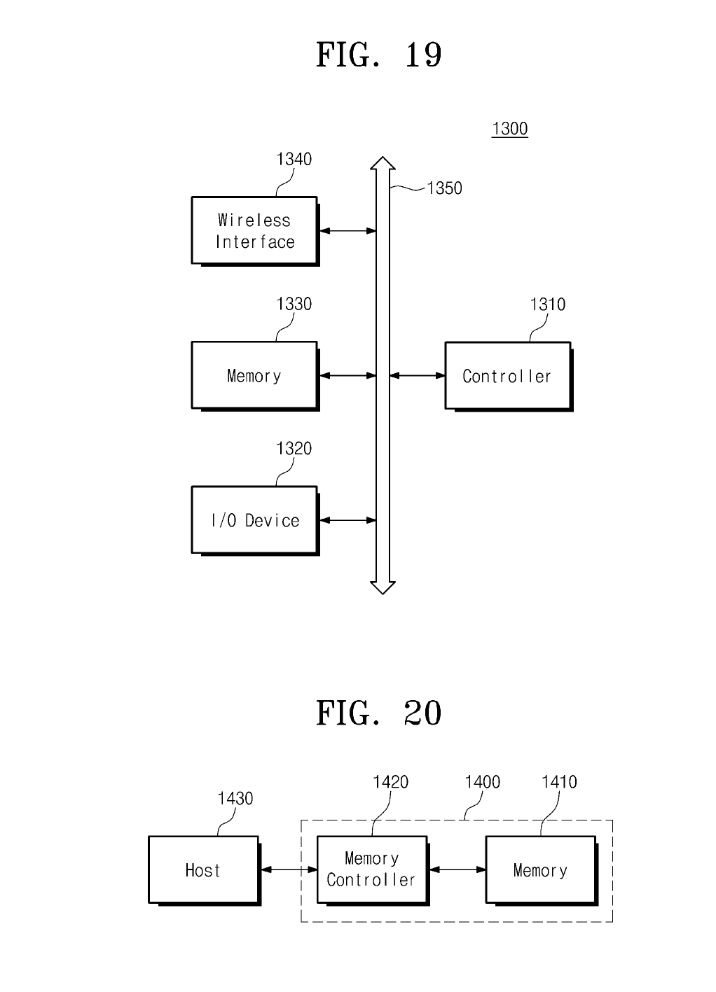

FIGS. 19 and 20 are block diagrams schematically illustrating electronic devices including a magnetic memory device according to example embodiments of the inventive concepts.

Referring to FIG. 19, an electronic device 1300 including a magnetic memory device according to example embodiments of the inventive concept may be used in one of a personal digital assistant (PDA), a laptop computer, a mobile computer, a web tablet, a wireless phone, a cell phone, a digital music player, a wired or wireless electronic device, or a complex electronic device including a combination of such functionalities. The electronic device 1300 may include a controller 1310, an input/output device 1320 (e.g., a keypad, a keyboard, a display), a memory 1330, and a wireless interface 1340 that are combined to each other through a bus 1350. The controller 1310 may include, for example, at least one microprocessor, a digital signal process, a microcontroller, and so forth. The memory 1330 may be configured to store a command code to be used by the controller 1310 or by user data. The memory 1330 may include a magnetic memory device according to example embodiments of inventive concepts. The electronic device 1300 may use a wireless interface 1340 configured to transmit data to and/or receive data from a wireless communication network using a RF (radio frequency) signal. The wireless interface 1340 may include, for example, an antenna, a wireless transceiver, and so forth. The electronic system 1300 may be used in a communication interface protocol of a communication system according to a standard such as CDMA, GSM, NADC, E-TDMA, WCDMA, CDMA2000, Wi-Fi, Muni Wi-Fi, Bluetooth, DECT, Wireless USB, Flash-OFDM, IEEE 802.20, GPRS, iBurst, WiBro, WiMAX, WiMAX-Advanced, UMTS-TDD, HSPA, EVDO, LTE-Advanced, MMDS, etc.

Hereinafter, a memory system including a magnetic memory device according to example embodiments of inventive concepts will be described with reference to FIG. 20. A memory system 1400 may include a memory device 1410 for storing relatively large quantities of data and a memory controller 1420. The memory controller 1420 controls the memory device 1410 so as to read data stored in the memory device 1410 or to write data into the memory device 1410 in response to a read/write request of a host 1430. The memory controller 1420 may include an address mapping table for mapping an address provided from the host 1430 (e.g., a mobile device or a computer system) into a physical address of the memory device 1410. The memory device 1410 may be a semiconductor device according to example embodiments of inventive concept.

The magnetic memory devices disclosed above may be encapsulated using various and diverse packaging techniques. For example, magnetic memory devices according to the aforementioned embodiments may be encapsulated using any one of a package on package (POP) technique, a ball grid array (BGA) technique, a chip scale package (CSP) technique, a plastic leaded chip carrier (PLCC) technique, a plastic dual in-line package (PDIP) technique, a die in waffle pack technique, a die in wafer form technique, a chip on board (COB) technique, a ceramic dual in-line package (CERDIP) technique, a plastic quad flat package (PQFP) technique, a small outline package (SOIC) technique, a shrink small outline package (SSOP) technique, a thin small outline package (TSOP) technique, a thin quad flat package (TQFP) technique, a system in package (SIP) technique, a multi-chip package (MCP) technique, a wafer-level fabricated package (WFP) technique and a wafer-level processed stack package (WSP) technique.

The package in which the magnetic memory device according to one of the above embodiments is mounted may further include at least one semiconductor device (e.g., a controller and/or a logic device) that controls the magnetic memory device.

According to exemplary embodiments of the inventive concepts, a magnetic memory device may include a magnetic tunnel junction and a pinned magnetic pattern horizontally separated from the magnetic tunnel junction. The pinned magnetic pattern allows the magnetic tunnel junction to be operated with higher stability, a lower operation current, and a higher operation speed. Further, since the pinned magnetic pattern is formed spaced apart from the magnetic tunnel junction in a horizontal direction, it is possible to reduce a total thickness of the magnetic tunnel junction and consequently improve structural stability of the magnetic tunnel junction.

While example embodiments of the inventive concepts have been particularly shown and described, it will be understood by one of ordinary skill in the art that variations in form and detail may be made therein without departing from the spirit and scope of the attached claims.

What is claimed is:

1. A semiconductor device, comprising:
magnetic tunnel junctions spaced apart from each other on a substrate, each of the magnetic tunnel junctions including a free magnetic pattern, a first pinned magnetic pattern, and a tunnel barrier pattern therebetween; and
a separation structure between the magnetic tunnel junctions,
wherein the separation structure includes a second pinned magnetic pattern and a first insulating pattern.

2. The device of claim 1, further comprising a capping layer covering side surfaces of the magnetic tunnel junctions,
wherein the magnetic tunnel junctions and the second pinned magnetic pattern are spaced apart from each other with the capping layer interposed therebetween.

3. The device of claim 2, wherein the capping layer extends between the separation structure and the substrate, and
the second pinned magnetic pattern has a bottom surface in direct contact with the capping layer.

4. The device of claim 1, wherein the separation structure further comprise a second insulating pattern, which is vertically spaced apart from the first insulating pattern with the second pinned magnetic pattern interposed therebetween.

5. The device of claim 1, further comprising:
bottom electrodes below the magnetic tunnel junctions; and
top electrodes on the magnetic tunnel junctions,
wherein, when viewed in plan view, each of the magnetic tunnel junctions is overlapped with a corresponding one of the bottom electrodes and a corresponding one of the top electrodes.

6. The device of claim 5, wherein the second pinned magnetic pattern is stacked on the first insulating pattern and has a top surface substantially coplanar with those of the top electrodes.

7. The device of claim 1, wherein each of the magnetic tunnel junctions further comprises a third pinned magnetic pattern,
the first and third pinned magnetic patterns are vertically spaced apart from each other with the free magnetic pattern interposed therebetween.

8. The device of claim 1, wherein the first and second pinned magnetic patterns have first and second magnetization directions, respectively, which are parallel, antiparallel, or perpendicular to each other, and each of which is fixed.

9. The device of claim 1, wherein the second pinned magnetic pattern comprises a plurality of patterns, which are spaced apart from each other, between the magnetic tunnel junctions, and
when viewed in plan view, the magnetic tunnel junctions and the patterns of the second pinned magnetic pattern are alternatingly arranged in a specific direction.

10. The device of claim 1, wherein, when viewed in plan view, the separation structure extends in between the magnetic tunnel junctions to enclose each of the magnetic tunnel junctions.

11. The device of claim 1, further comprising:
a cell gate electrode provided on the substrate;
a first impurity region and a second impurity region in portions of the substrate positioned at both sides of the cell gate electrode;
a source line coupled to the first impurity region; and
a contact coupled to the second impurity region,
wherein the contact is connected to a corresponding one of the magnetic tunnel junctions.

12. The device of claim 11, wherein, when viewed in plan view, the separation structure is overlapped with the source line and is spaced apart from the contact.

13. A semiconductor device, comprising:
magnetic tunnel junctions spaced apart from each other on a substrate, each of the magnetic tunnel junctions comprising a free magnetic pattern, a first pinned magnetic pattern, and a tunnel barrier pattern therebetween; and
second pinned magnetic patterns spaced apart from each other and interposed between the magnetic tunnel junctions,
wherein when viewed in plan view, the magnetic tunnel junctions and the second pinned magnetic patterns are alternatingly arranged in a specific direction.

14. The device of claim 13, wherein the magnetic tunnel junctions are arranged along first and second directions crossing each other to have a two-dimensional arrangement,
the second pinned magnetic patterns are arranged between the magnetic tunnel junctions and in a third direction crossing both of the first and second directions, and
all of the first, second, and third directions are parallel to a top surface of the substrate.

15. The device of claim 13, further comprising:
a capping layer covering side surfaces of the magnetic tunnel junctions and extending in between the second pinned magnetic patterns and the substrate; and
top electrodes provided on the magnetic tunnel junctions,
wherein the second pinned magnetic patterns have bottom surfaces, which are in direct contact with a top surface of the capping layer, and top surfaces, which are substantially coplanar with those of the top electrodes.

16. A semiconductor device, comprising:
magnetic tunnel junctions spaced apart from each other on a substrate, each of the magnetic tunnel junctions including a free magnetic pattern, a first pinned magnetic pattern, and a tunnel barrier pattern therebetween;
bottom electrodes below the magnetic tunnel junctions and overlapped with the magnetic tunnel junctions, respectively, when viewed in plan view; and
a second pinned magnetic pattern filling gap regions between the bottom electrodes.

17. The device of claim 16, wherein the second pinned magnetic pattern has a top surface coplanar with those of the bottom electrodes,
when viewed in plan view, the second pinned magnetic pattern encloses the magnetic tunnel junctions.

18. The device of claim 16, wherein the second pinned magnetic pattern has side surfaces in direct contact with those of the bottom electrodes.

19. The device of claim 16, further comprising:
a capping layer covering side surfaces of the magnetic tunnel junctions; and
an interlayered insulating layer on the capping layer,
wherein, when viewed in a vertical section, the capping layer is interposed between the second pinned magnetic pattern and the interlayered insulating layer.

20. The device of claim 16, further comprising:
a cell gate electrode on the substrate;
a first impurity region and a second impurity region in portions of the substrate positioned at both sides of the cell gate electrode;
a source line coupled to the first impurity region; and
a contact coupled to the second impurity region,
wherein the contact is connected to a corresponding one of the magnetic tunnel junctions,
when viewed in plan view, the second pinned magnetic pattern is overlapped with the source line and is spaced apart from the contact.
